(19) United States
(12) Patent Application Publication
(10) Pub. No.: US 2021/0391519 A1
(43) Pub. Date: Dec. 16, 2021

(54) LIGHT EMITTING DEVICE AND MANUFACTURING METHOD THEREOF

(71) Applicant: Genesis Photonics Inc., Tainan City (TW)

(72) Inventors: Yi-Ru Huang, Tainan City (TW); Tung-Lin Chuang, Tainan City (TW); Chi-Hao Cheng, Tainan City (TW)

(73) Assignee: Genesis Photonics Inc., Tainan City (TW)

(21) Appl. No.: 17/344,872

(22) Filed: Jun. 10, 2021

Related U.S. Application Data
(60) Provisional application No. 63/037,009, filed on Jun. 10, 2020.

(51) Int. Cl. H01L 33/62; H01L 33/22; H01L 33/46; H01L 33/40

(52) U.S. Cl. CPC H01L 33/62; H01L 33/22; H01L 33/46; H01L 2933/0066; H01L 2933/0016; H01L 2933/0025; H01L 33/40

(57) ABSTRACT

A light emitting device includes a growth substrate, a light emitting component, a first conductive bump and a second conductive bump. The light emitting component is disposed on the growth substrate, including a first type semiconductor layer, a second type semiconductor layer, a light emitting layer, an ohmic contact layer, a first conductor layer, and a second conductor layer. The light emitting layer and the second type semiconductor layer are penetrated by a trench. The ohmic contact layer is disposed on the first type semiconductor layer and is disposed in the trench. The ohmic contact layer is electrically connected to the first type semiconductor layer. The first conductor layer is disposed on the first type semiconductor layer and is disposed in the trench. The first conductor layer covers the ohmic contact layer. The second conductor layer is disposed on the second type semiconductor layer, and is electrically connected to the second type semiconductor layer. A manufacturing method of the light emitting device is also provided.

### CROSS-REFERENCE TO RELATED APPLICATION

This application claims the priority benefit of U.S. provisional application Ser. No. 63/037,009, filed on Jun. 10, 2020. The entirety of the above-mentioned patent application is hereby incorporated by reference herein and made a part of this specification.

### BACKGROUND

### Technical Field

The disclosure relates to a semiconductor device and a manufacturing method thereof; particularly, the disclosure relates to a light emitting device and a manufacturing method thereof.

### Description of Related Art

Generally, a light emitting diode (LED) includes a vertical type LED and a flip-chip type LED. The flip-chip type LED includes a first type semiconductor layer, a light emitting layer, a second type semiconductor layer, a first metal layer, a second metal layer, a first insulation layer, a first current conducting layer, a second current conducting layer, a second insulation layer, a first bonding layer, and a second bonding layer. The first type semiconductor layer has a first portion and a second portion. The light emitting layer is disposed on the first portion of the first type semiconductor layer. The second portion of the first type semiconductor layer extends outwardly from the first portion to protrude out of an area occupied by the light emitting layer. The second type semiconductor layer is disposed on the light emitting layer. The first metal layer is disposed on the second portion of the first type semiconductor layer and electrically connected to the first type semiconductor layer. The second metal layer is disposed on and electrically connected to the second type semiconductor layer. The first insulation layer covers the first metal layer and the second metal layer, and has a plurality of penetrating openings exposing the first metal layer and the second metal layer, respectively. The first current conducting layer and the second current conducting layer are disposed on the first insulation layer and fill a plurality of penetrating openings of the first insulation layer, so as to be electrically connected to the first metal layer and the second metal layer, respectively. The second insulation layer covers the first current conducting layer and the second current conducting layer and has a plurality of penetrating openings overlapping the first current conducting layer and the second current conducting layer, respectively. The first bonding layer and the second bonding layer are disposed on the second insulation layer and fill the penetrating openings of the second insulation layer, so as to be electrically connected to the first current conducting layer and the second current conducting layer, respectively. The first bonding layer and the second bonding layer are configured to be eutectically bonded to an external circuit board. However, in the process of arranging the first metal layer, it is difficult to form an ohmic contact between the first metal layer and the first type semiconductor layer, which may pose a negative impact on the performance of the LED.

### SUMMARY

The disclosure provides a light emitting device with good performance and a manufacturing method thereof.

In an embodiment of the disclosure, a light emitting device includes a growth substrate, a light emitting component, a first conductive bump, and a second conductive bump. The light emitting component is disposed on the growth substrate. The light emitting component includes a first type semiconductor layer, a second type semiconductor layer, a light emitting layer, an ohmic contact layer, a first conductor layer, and a second conductor layer. The light emitting layer is located between the first type semiconductor layer and the second type semiconductor layer. The light emitting layer and the second type semiconductor layer have a trench penetrating the light emitting layer and the second type semiconductor layer. The ohmic contact layer is disposed on the first type semiconductor layer, located in the trench, and electrically connected to the first type semiconductor layer. The first conductor layer is disposed on the first type semiconductor layer and located in the trench. The first conductor layer covers the ohmic contact layer and is electrically connected to the ohmic contact layer. The second conductor layer is disposed on and electrically connected to the second type semiconductor layer. The first conductive bump is electrically connected to the first type semiconductor layer through the first conductor layer and the ohmic contact layer. The second conductive bump is electrically connected to the second type semiconductor layer through the second conductor layer.

According to an embodiment of the disclosure, the first conductor layer and the first type semiconductor layer are directly electrically connected.

According to an embodiment of the disclosure, the light emitting component further includes a first current conducting layer and a second current conducting layer. The first current conducting layer is disposed on the first conductor layer, and the first current conducting layer is electrically connected to the first type semiconductor layer through the first conductor layer and the ohmic contact layer. The second current conducting layer is disposed on the second conductor layer, and the second current conducting layer is electrically connected to the second conductor layer and the second type semiconductor layer.

According to an embodiment of the disclosure, the first conductor layer is located between the ohmic contact layer and the first current conducting layer.

According to an embodiment of the disclosure, a material of the ohmic contact layer includes a III-V group compound.

According to an embodiment of the disclosure, a lattice constant of the ohmic contact layer does not match a lattice constant of the first type semiconductor layer.

According to an embodiment of the disclosure, the light emitting device further includes a stack of insulation layers, a first connection layer, and a second connection layer. The stack of insulation layers is disposed on the light emitting component and includes a first insulation layer and a second insulation layer. The second insulation layer is disposed on first insulation layer. The first connection layer is disposed on the first insulation layer. The first connection layer is electrically connected to the first type semiconductor layer through the first conductor layer. The second connection layer is disposed on the first insulation layer. The second connection layer is electrically connected to the second type semiconductor layer through the second conductor layer. The second insulation layer covers the first connection layer and the second connection layer. The first connection layer is electrically insulated from the second connection layer by the first insulation layer and the second insulation layer.

According to an embodiment of the disclosure, the first conductive bump is electrically connected to the first conductor layer through the first connection layer. The second conductive bump is electrically connected to the second conductor layer through the second connection layer.

According to an embodiment of the disclosure, the light emitting device further includes a third connection layer in an electrically floating state, and the third connection layer is disposed on the first insulation layer. The third connection layer is electrically insulated from the first connection layer or the second connection layer by the first insulation layer and the second insulation layer.

According to an embodiment of the disclosure, the light emitting device further includes an undoped semiconductor layer. The undoped semiconductor layer is located between the growth substrate and the light emitting component.

According to an embodiment of the disclosure, the ohmic contact layer includes a plurality of vias and island portions surrounding the vias. The first conductor layer fills the vias for to contact the first type semiconductor layer.

According to an embodiment of the disclosure, the ohmic contact layer includes a rough surface. The rough surface includes a plurality of micro-structures.

In an embodiment of the disclosure, a light emitting device includes a growth substrate and a light emitting component. The light emitting component is disposed on the growth substrate. The light emitting component includes a first type semiconductor layer, a second type semiconductor layer, a light emitting layer, an ohmic contact layer, a first conductor layer, and a second conductor layer. The light emitting layer is located between the first type semiconductor layer and the second type semiconductor layer. The light emitting layer and the second type semiconductor layer have a trench penetrating the light emitting layer and the second type semiconductor layer. The ohmic contact layer is disposed on the first type semiconductor layer, located in the trench, and electrically connected to the first type semiconductor layer. The ohmic contact layer has a plurality of finger portions. The first conductor layer is disposed on an upper surface of the ohmic contact layer and located in the trench. The first conductor layer is electrically connected to the ohmic contact layer. The second conductor layer is disposed on and electrically connected to the second type semiconductor layer.

According to an embodiment of the disclosure, the finger portions are located in the trench, and space exists between the finger portions and the second type semiconductor layer.

According to an embodiment of the disclosure, the light emitting component further includes an insulative reflection layer disposed on the light emitting layer, the second type semiconductor layer, and the second conductor layer. The insulative reflection layer includes a plurality of openings.

According to an embodiment of the disclosure, the light emitting device further includes a first current conducting layer and a second current conducting layer. The first current conducting layer is disposed on the first conductor layer. The first current conducting layer is electrically connected to the first type semiconductor layer through the first conductor layer and the ohmic contact layer. The second current conducting layer is disposed on the insulative reflection layer. The insulative reflection layer is electrically connected to the second conductor layer through the openings, so as to be electrically connected to the second type semiconductor layer.

According to an embodiment of the disclosure, the light emitting device further includes a stack of insulation layers, a first connection layer, and a second connection layer. The stack of insulation layers is disposed on the light emitting component and includes a reflection layer and an insulation layer disposed on the reflection layer. The first connection layer is disposed on the reflection layer. The first connection layer is electrically connected to the first type semiconductor layer through the first current conducting layer. The second connection layer is disposed on the reflection layer. The second connection layer is electrically connected to the second type semiconductor layer through the second current conducting layer. The insulation layer covers the first connection layer and the second connection layer.

In an embodiment of the disclosure, a manufacturing method of a light emitting device includes following steps. A growth substrate is provided. An undoped semiconductor layer is formed on the growth substrate. A light emitting component is formed on the undoped semiconductor layer. The step of forming the light emitting component includes following steps. A first type semiconductor layer is formed on the undoped semiconductor layer. A light emitting layer is formed on the first type semiconductor layer. A second type semiconductor layer is formed on the light emitting layer. A first etching process is performed to pattern the light emitting layer and the second type semiconductor layer. At least one first trench is formed in the light emitting layer and the second type semiconductor layer and exposes the first type semiconductor layer. A sacrificial layer that covers the first type semiconductor layer, the light emitting layer, and the second type semiconductor layer is formed. A second etching process is performed to pattern the sacrificial layer. At least one second trench is formed in the sacrificial layer. An orthogonal projection of the at least one second trench on the growth substrate is located in an orthogonal projection of the at least one first trench on the growth substrate. An ohmic contact layer is formed in the at least one second trench. The sacrificial layer is removed. A first conductor layer is formed on the ohmic contact layer and is electrically connected to the ohmic contact layer. A second conductor layer is formed on the second type semiconductor layer. A first current conducting layer is formed and electrically connected to the first conductor layer. A second current conducting layer is formed and electrically connected to the second conductor layer. A first insulation layer is formed on the light emitting component. The first insulation layer has a plurality of openings respectively exposing the first current conducting layer and the second current conducting layer. A first connection layer, a second connection layer, and a third connection layer are formed on the first insulation layer. The first connection layer and the second connection layer are correspondingly electrically connected to the first current conducting layer and the second current conducting layer through the openings of the first insulation layer, respectively. The third connection layer is in an electrically floating state. A second insulation layer is formed on the first insulation layer. The second insulation layer isolates the first connection layer, the second connection layer, and the third connection layer. The second insulation layer includes a plurality of openings. A first conductive bump and a second conductive bump are formed. The first conductive bump and the second conductive bump are correspondingly electrically connected to the first connection layer and the second connection layer through the openings of the second insulation layer, respectively.

According to an embodiment of the disclosure, the step of forming the light emitting component further includes forming an insulative reflection layer on the light emitting layer, the second type semiconductor layer, and the second conductor layer. The second current conducting layer is electrically connected to the second conductor layer through a plurality of openings of the insulative reflection layer.

According to an embodiment of the disclosure, the at least one first trench has a first width. The at least one second trench has a second width. The first width is greater than the second width.

Based on the above, the LED provided in one or more embodiments of the disclosure includes the ohmic contact layer electrically connected to the first type semiconductor layer, and the first conductor layer contacts the ohmic contact layer; thereby, the first conductor layer made of metal and the ohmic contact layer having an epitaxial structure may form a structure with low resistance and ohmic contact characteristics on the first type semiconductor layer. As such, electrical properties of the first type semiconductor layer may be improved, and the light emitting device may have favorable performance and quality. In addition, the manufacturing process of the light emitting device may be simple and cost-saving.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic top view of a light emitting device according to an embodiment of the disclosure.

FIG. 2A to FIG. 2N are schematical cross-sectional views illustrating a manufacturing method of the light emitting device in FIG. 1 along a cross-sectional line U-U′.

FIG. 2F is a schematic partially enlarged view of the region R1 in FIG. 2E.

FIG. 2H is a schematic partially enlarged view of the region R2 in FIG. 2G.

FIG. 3A to FIG. 3D are schematical cross-sectional views illustrating a manufacturing method of a light emitting device according to another embodiment of the disclosure.

FIG. 3B is a schematic partially enlarged view of an ohmic contact layer according to another embodiment of the disclosure.

FIG. 4A to FIG. 4C are schematic cross-sectional views illustrating a manufacturing method of a light emitting device according to another embodiment of the disclosure.

FIG. 4A is a schematic partially enlarged view of an ohmic contact layer according to another embodiment of the disclosure.

FIG. 4B is a schematic partially enlarged view of an ohmic contact layer according to another embodiment of the disclosure.

FIG. 5A to FIG. 5B are schematic cross-sectional views illustrating a manufacturing method of a light emitting device according to another embodiment of the disclosure.

FIG. 5A is a schematic partially enlarged view of an ohmic contact layer according to another embodiment of the disclosure.

FIG. 6A to FIG. 6F are schematic cross-sectional views illustrating a manufacturing method a light emitting device according to another embodiment of the disclosure.

FIG. 7A to FIG. 7C are schematic cross-sectional views illustrating a manufacturing method of a light emitting device according to still another embodiment of the disclosure.

### DESCRIPTION OF THE EMBODIMENTS

References will now be made in detail to the exemplary embodiments of the disclosure, and examples of the exemplary embodiments are illustrated in the drawings. Whenever possible, the same reference numbers and symbols used in the drawings and descriptions serve to represent the same or similar parts.

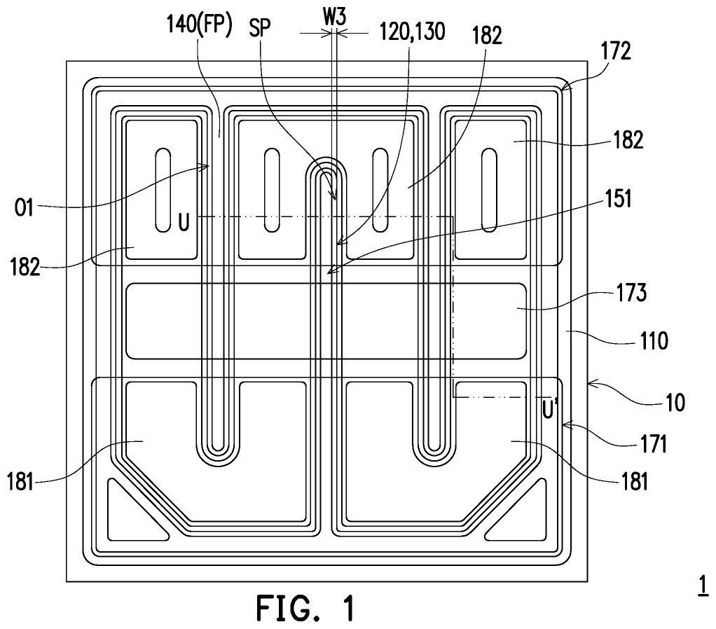

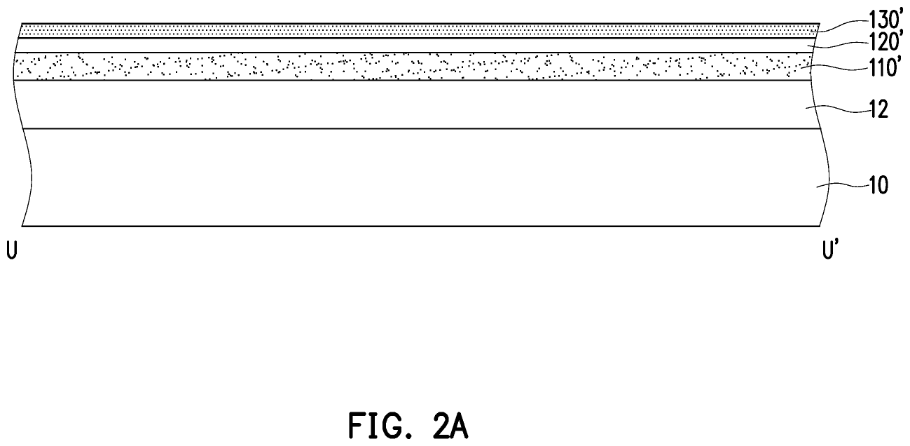

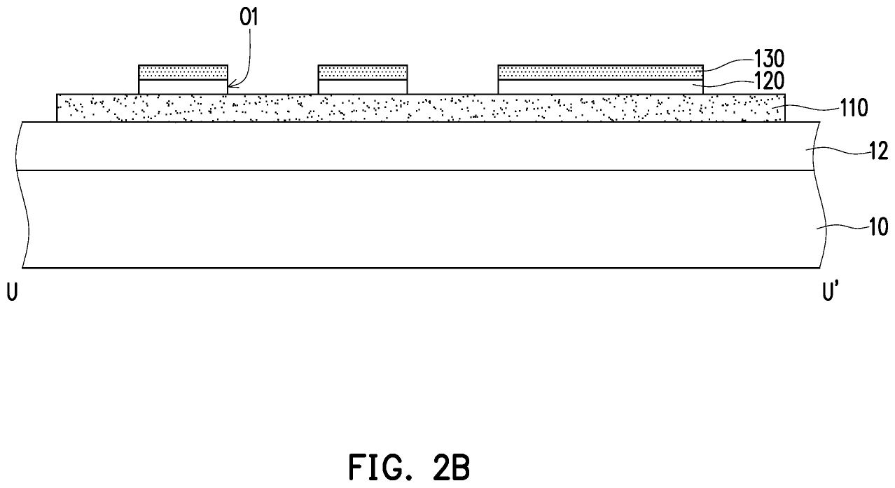

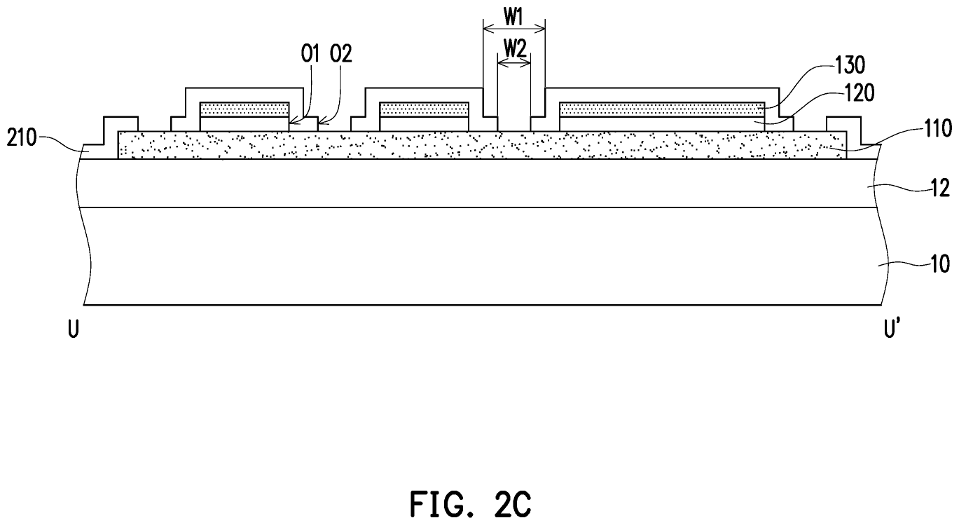

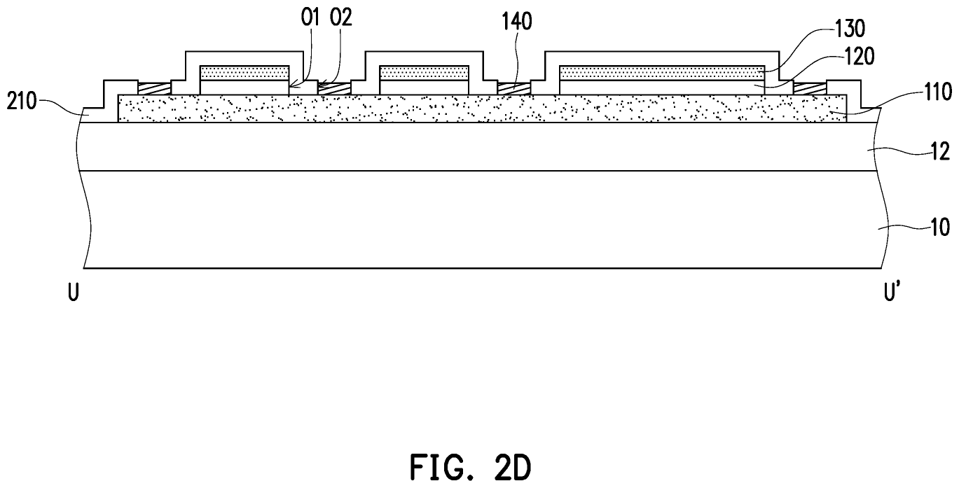

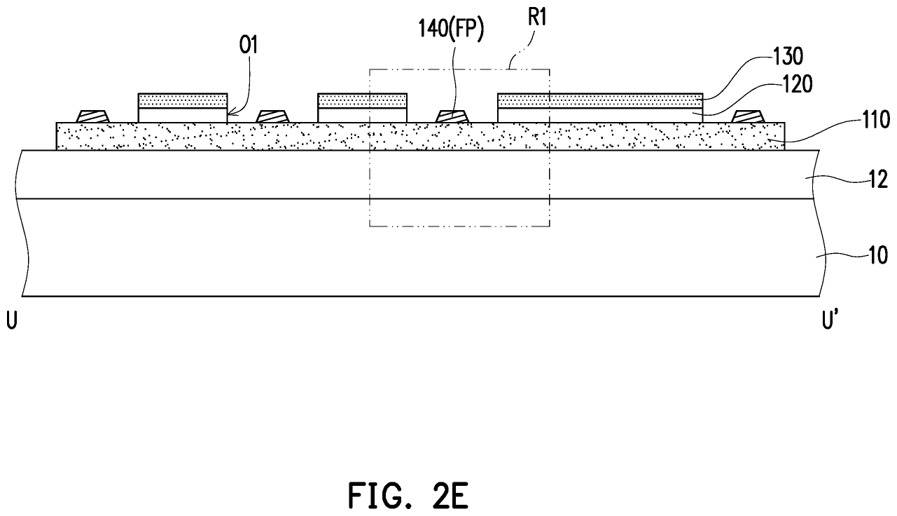

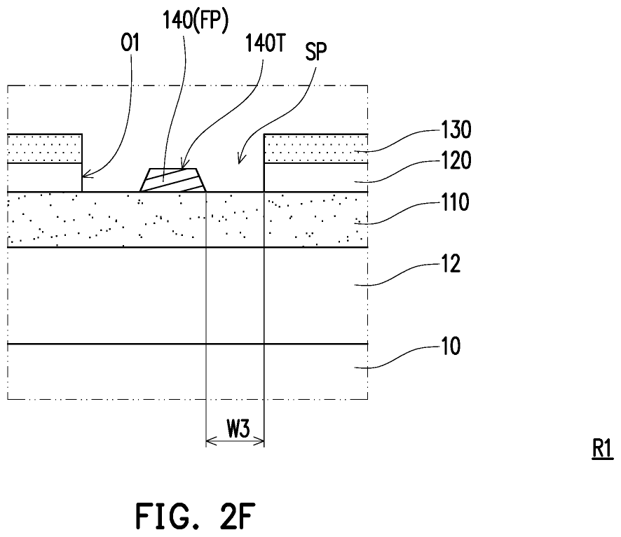

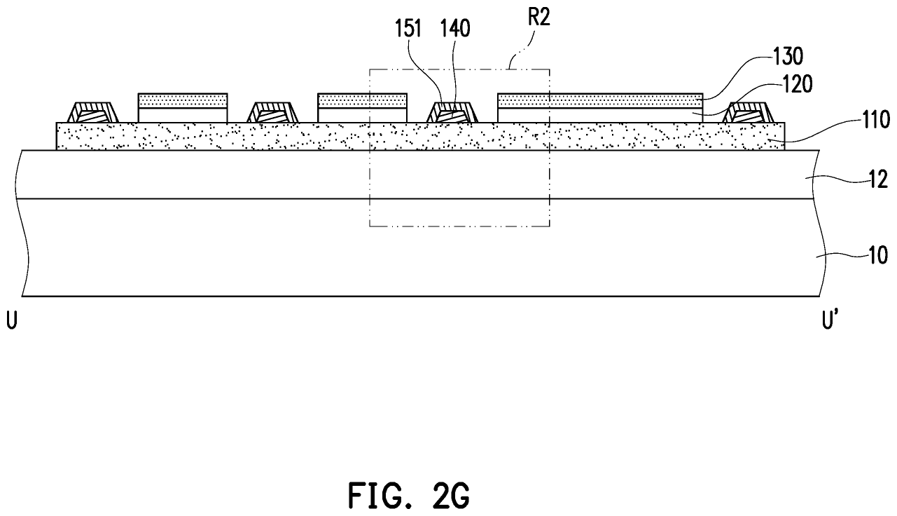

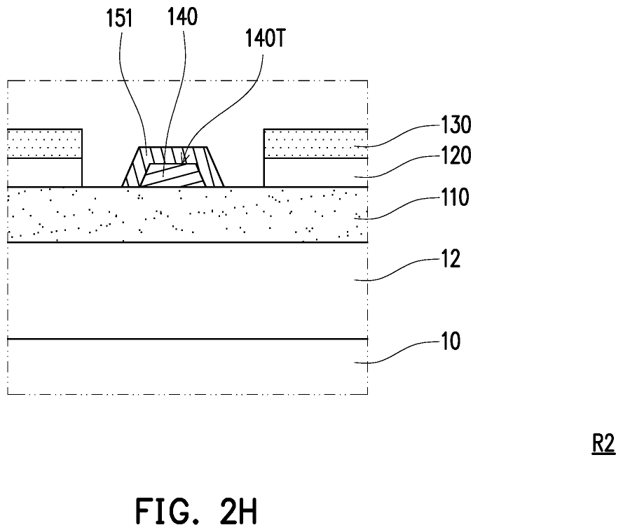

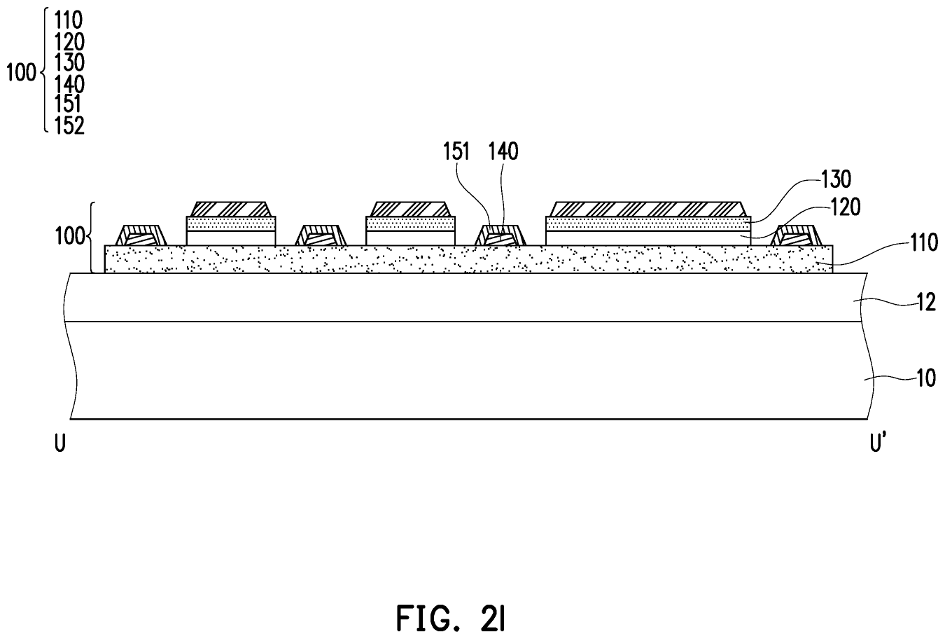

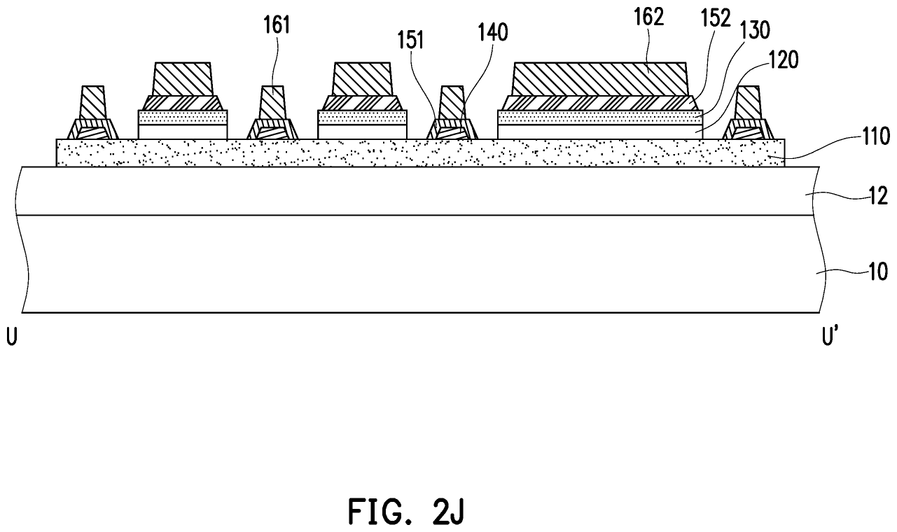

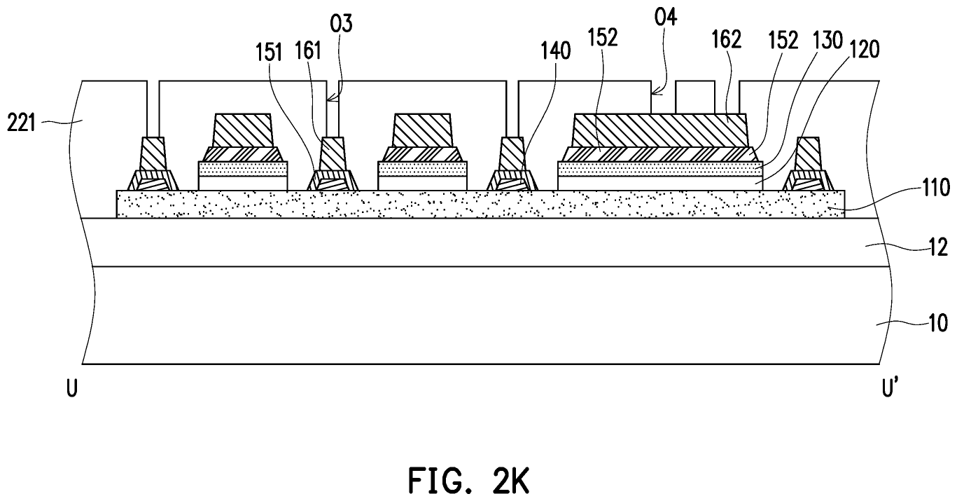

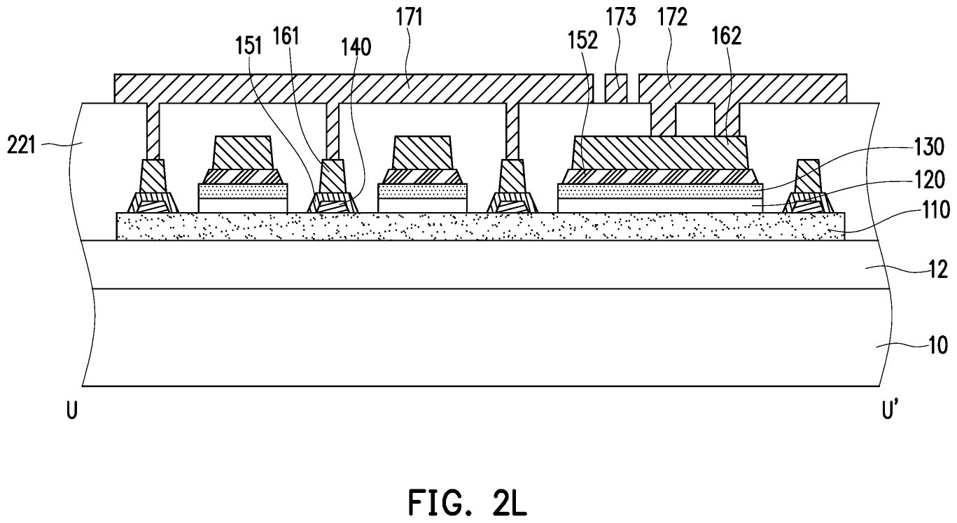

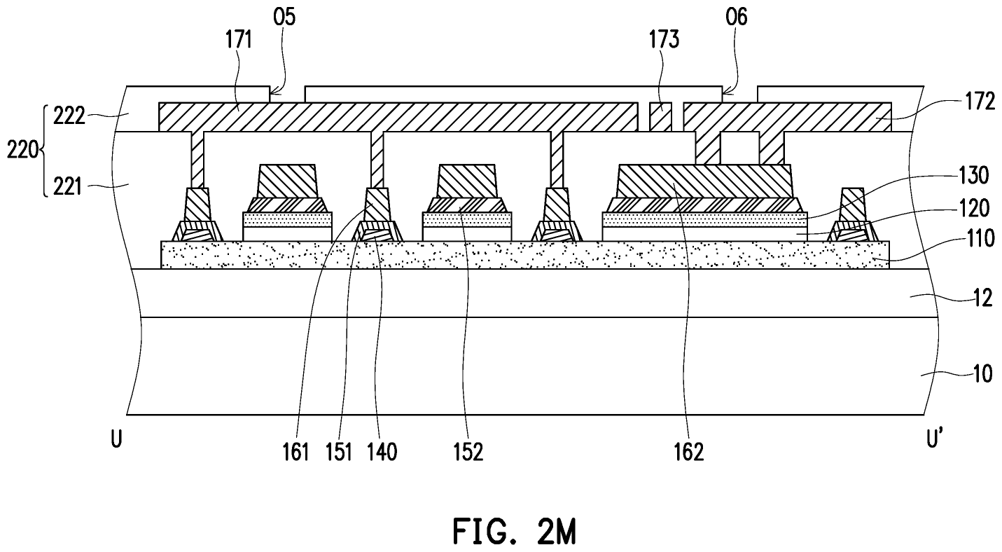

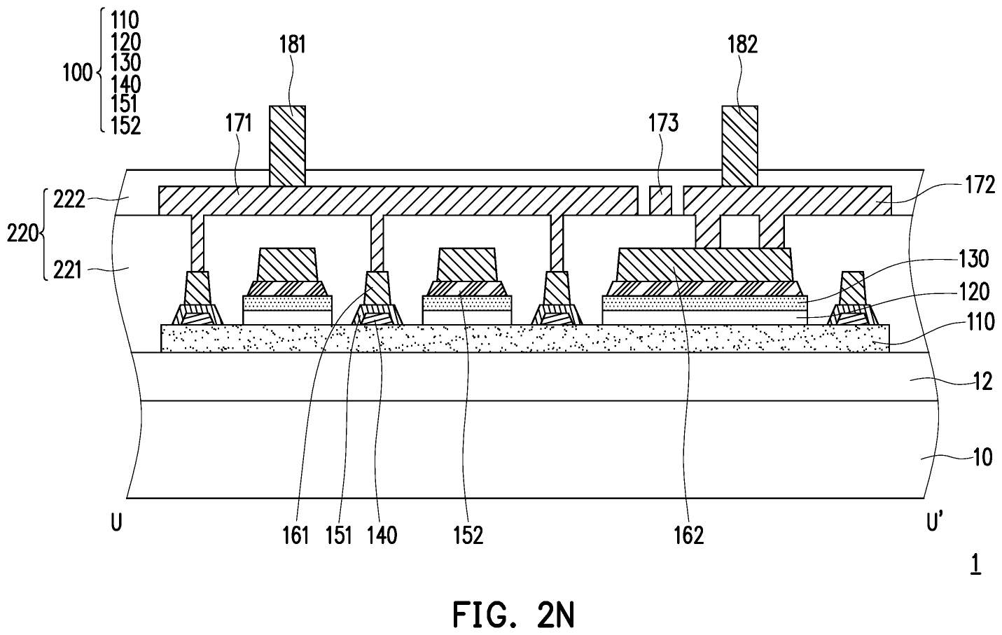

FIG. 1 is a schematic top view of a light emitting device according to an embodiment of the disclosure. FIG. 2A to FIG. 2N are schematical cross-sectional views illustrating a manufacturing method of the light emitting device in FIG. 1 along a cross-sectional line U-U′. For the clarity of the drawings and easy explanation, some components are omitted from FIG. 1 and FIG. 2A to FIG. 2N. With reference to FIGS. 1 and FIG. 2N, a light emitting device 1 is a flip chip type light emitting diode (LED). The light emitting device 1 includes a growth substrate 10, a light emitting component 100 disposed on the growth substrate 10, and a first conductive bump 181 and a second conductive bump 182 which are electrically connected to the light emitting component 100. The light emitting component 100 includes a first type semiconductor layer 110, a second type semiconductor layer 130, a light emitting layer 120 located between the first type semiconductor layer 110 and the second type semiconductor layer 130, a first conductor layer 151, and a second conductor layer 152. The first conductor layer 151 is disposed on and electrically connected to the first type semiconductor layer 110. The second conductor layer 152 is disposed on and electrically connected to the second type semiconductor layer 130. The first conductive bump 181 is electrically connected to the first type semiconductor layer 110 through the first conductor layer 151. The second conductive bump 182 is electrically connected to the second type semiconductor layer 130 through the second conductor layer 152. According to an embodiment of the disclosure, the light emitting device 1 further includes an ohmic contact layer 140 disposed on and electrically connected to the first type semiconductor layer 110. The first conductor layer 151 is disposed on and electrically connected to the ohmic contact layer 140. Since the ohmic contact layer 140 is disposed between the first type semiconductor layer 110 and the first conductor layer 151, an issue of the difficulty in forming an ohmic contact between the first conductor layer 151 made of metal and the first type semiconductor layer 110 may be solved. In addition, the ohmic contact layer 140 and the first conductor layer 151 may have low resistance and ohmic contact characteristics, and thus the quality and performance of the light emitting device 1 may be improved.

With reference to FIG. 1, the light emitting device 1 substantially includes the growth substrate 110 and a light emitting unit. The light emitting unit includes, for instance, the first type semiconductor layer 110, the light emitting layer 120, the second type semiconductor layer 130, the ohmic contact layer 140, the first conductor layer 151, and the second conductor layer 152 (not shown in FIG. 1). The light emitting device 1 further includes a first connection layer 171 and a second connection layer 172. The first connection layer 171 is electrically connected to the first conductor layer 151. The second connection layer 172 is electrically connected to the second conductor layer 152.

It can be seen from FIG. 1 that the first connection layer 171 and the second connection layer 172 may be arranged opposite to each other and may be separated from each other. The light emitting layer 120 and the second type semiconductor layer 130 may have a trench O1 penetrating the light emitting layer 120 and the second type semiconductor layer 130. As shown in the top view, the trench O1 may be a gap and may extend toward the inside of the first connection layer 171 or the second connection layer 172. The trench O1 may be defined by sidewalls of the light emitting layer 120 and the second type semiconductor layer 130 and is isolated from sidewalls of the first connection layer 171 or the second connection layer 172.

In some embodiments, the ohmic contact layer 140 is disposed in the trench O1 and is isolated from sidewalls of the trench O1 (i.e., sidewalls of the light emitting layer 120 and the second type semiconductor layer 130). Specifically, an orthogonal projection of the ohmic contact layer 140 on the growth substrate 110 is located in an orthogonal projection of the trench O1 on the growth substrate 110. Space SP exists between the ohmic contact layer 140 and the trench O1, and the space SP has a width W3. In some embodiments, the width W3 is, for instance, 1 μm to 30 μm, which should not be construed as a limitation in the disclosure.

It can be seen from FIG. 1 that a portion of the ohmic contact layer 140 may extend along the trench O1. The extended portion of the ohmic contact layer 140 may be defined as finger portions FP. The finger portions FP do not overlap the light emitting layer 120 and the second type semiconductor layer 130. In some embodiments, the contour of the finger portions FP is arranged around the light emitting layer 120 and the second type semiconductor layer 130. In other embodiments, the ohmic contact layer 140 further includes a connection portion (not shown) to connect a plurality of finger portions FP, which should not be construed as a limitation in the disclosure.

It can be seen from FIG. 1 that the first conductor layer 151 conformally covers the ohmic contact layer 140, for instance. A portion of the first conductor layer 151 is disposed in the trench O1 and may extend along the trench O1. The contour of the first conductor layer 151 is arranged around the light emitting layer 120 and the second type semiconductor layer 130, which should not be construed as a limitation in the disclosure. In other embodiments, the first conductor layer 151 may partially overlap the ohmic contact layer 140.

In some embodiments, the first connection layer 171 may be electrically connected to the first conductor layer 151 and the ohmic contact layer 140. The second connection layer 172 may be electrically connected to the second conductor layer 152 (as shown in FIG. 2N). The first conductive bump 181 and the second conductive bump 182 are electrically connected to the first connection layer 171 and the second connection layer 172, respectively. Under the above configuration, the first conductive bump 181 and the second conductive bump 182 may be respectively applied as a positive electrode or a negative electrode of the light emitting device 1, and are electrically connected to external circuit components. Thus, the light emitting device 1 may be applied to a visible light emitting device, an ultraviolet light emitting device, or any other appropriate light emitting device, which should not be construed as a limitation in the disclosure.

An embodiment provided below serves to briefly describe a manufacturing process of the light emitting device 1.

With reference to FIG. 2A, a growth substrate 10 is provided. A material of the growth substrate 170 is, for instance, a sapphire substrate with a C-Plane, an R-Plane, or an A-Plane or any other transparent material. In addition, a monocrystalline compound whose lattice constant is close to a lattice constant of the first type semiconductor layer 110 is also adapted to be applied as the material of the growth substrate 10. In some embodiments, the material of the growth substrate may further include silicon carbide (SiC), silicon (Si), aluminum nitride (AlN), gallium nitride (GaN), aluminum gallium nitride (AlGaN), or other suitable materials, which should not be construed as a limitation in the disclosure.

In an embodiment, an undoped semiconductor layer 12 may be selectively formed on the growth substrate 10. A material of the undoped semiconductor layer 12 is, for instance, undoped aluminum nitride, aluminum gallium nitride, or other suitable materials, which should not be construed as a limitation in the disclosure.

Stacked layers of light emitting components are formed on the undoped semiconductor layer 12. For instance, the undoped semiconductor layer 12 is located between the growth substrate 10 and the light emitting component. The stacked layers of the light emitting components provided in the embodiment include, for instance, a first type semiconductor material layer 110′, a light emitting material layer 120′, and a second type semiconductor material layer 130′ that are sequentially grown and stacked on the growth substrate 10. In other embodiments, the light emitting device 1 may not include the growth substrate 10 or the undoped semiconductor layer 12.

In some embodiments, the first type semiconductor material layer 110′ is, for instance, an N-type semiconductor layer, including an n-AlGaN-based material or an n-AlyGaN-based/n-AlxGaN-based material, (where x≠y), which should not be construed as a limitation in the disclosure. The second type semiconductor material layer 130′ is, for instance, a P-type semiconductor layer, including a p-AlGaN-based material or a p-AlGaN-based/p-GaN-based material, which should not be construed as a limitation in the disclosure.

In some embodiments, the light emitting material layer 120′ may have a quantum well (QW) structure. In other embodiments, the light emitting material layer 120′ may have a multiple quantum well (MQW) structure, wherein the MQW structure includes a plurality of quantum well layers and a plurality of quantum barrier layers alternately arranged in a repetitive manner. In addition, composition materials of the light emitting material layer 120′ layer 120′ include a compound semiconductor capable of emitting a light beam with a peak wavelength falling in the range of 220 nm to 300 nm (medium ultraviolet light) or 300 nm to 400 nm (near ultraviolet light). The material of the light emitting material layer 120′ includes a AlxGaN-based/AlyGaN-based material, and x≤y, which should not be construed as a limitation in the disclosure.

Under the above configuration, the light emitting component provided in an embodiment of the disclosure is, for instance, an ultraviolet LED.

With reference to FIG. 2B, a first etching process is performed to pattern the light emitting material layer 120′ and the second type semiconductor material layer 130′, so as to form the light emitting layer 120 and the second type semiconductor layer 130. The patterned light emitting layer 120 and the second type semiconductor layer 130 have a first trench O1 formed in the light emitting layer 120 and the second type semiconductor layer 130. The first trench O1 may expose a surface of the first type semiconductor material layer 110′ or the first type semiconductor layer 110. In some embodiments, sidewalls of the first trench O1 may be inclined, which should not be construed as a limitation in the disclosure. Another etching process may then be performed to pattern the first type semiconductor material layer 110′, so as to form the first type semiconductor layer 110. The first type semiconductor layer 110 is located on a portion of the undoped semiconductor layer 12, and the portion of the undoped semiconductor layer 12 may be exposed. The light emitting layer 120 is located on the first type semiconductor layer 110, and the second type semiconductor layer 130 is located on the light emitting layer 120.

With reference to FIG. 2C, a sacrificial layer 210 covering the first type semiconductor layer 110, the light emitting layer 120, and the second type semiconductor layer 130 is formed. In some embodiments, the sacrificial layer 210 may be disposed on the sidewalls of the light emitting layer 120 and the second type semiconductor layer 130 and may cover an upper surface of the second type semiconductor layer 130. A material of the sacrificial layer 210 includes an organic material or an inorganic material. The inorganic material may, for instance, include silicon dioxide (SiO₂), aluminum oxide (Al₂O₃), or silicon nitride (SiN), which should not be construed as a limitation in the disclosure.

A second etching process is then performed to pattern the sacrificial layer 210. At least one second trench O2 may be formed in the patterned sacrificial layer 210. An orthogonal projection of the second trench O2 on the growth substrate 10 is located in an orthogonal projection of the first trench O1 on the growth substrate 10. In some embodiments, the first trench O1 has a first width W1. The first width W1 may be defined as the maximum distance between opposite sidewalls of the first trench O1. The second trench O2 has a second width W2. The second width W2 may be defined as the maximum distance between opposite sidewalls of the second trench O2. The first width W1 is greater than the second width W2. In some embodiments, the first width W1 is, for instance, 3 μm to 100 μm. The second width W2 is, for instance, 1μm to 100 μm, which should not be construed as a limitation in the disclosure.

With reference to FIG. 2D, an ohmic contact layer 140 is formed in the second trench O2. Specifically, the step of forming the ohmic contact layer 140 may include performing a heating process on the growth substrate 10, wherein a heating temperature ranges from 100° C. to 1500° C., so as to grow crystals on the surface of the first type semiconductor layer 150 exposed by the sacrificial layer 210. In some embodiments, the heating process may further include doping silicon or a tetravalent element (such as carbon) into the ohmic contact layer 140. The ohmic contact layer 140 is an epitaxial structural layer, and its material includes GaN, gallium aluminum nitride, indium gallium nitride, and indium gallium aluminum nitride. In some embodiments, the material of the ohmic contact layer 140 includes a III-V group compound or the above-mentioned material doped with aluminum or indium, which should not be construed as a limitation in the disclosure. In addition, the ohmic contact layer 140 may be a semiconductor epitaxial layer doped with elements with high concentration. For instance, the ohmic contact layer 140 is doped with silicon with high concentration, and a carrier concentration after doping is 10¹⁷cm⁻³ to 10²⁰cm⁻³, which should not be construed as a limitation in the disclosure. In some embodiments, the ohmic contact layer 140 may have a monocrystalline structure, an amorphous structure, or a polycrystalline structure, which should not be construed as a limitation in the disclosure.

Please refer to FIG. 2E and FIG. 2F. FIG. 2F is a schematic partially enlarged view of the region R1 in FIG. 2E. The sacrificial layer 210 is removed. After the step of removing the sacrificial layer 210, the ohmic contact layer 140 may be located in the first trench O1 without contacting the light emitting layer 120 and the second type semiconductor layer 130. Space SP exists between the ohmic contact layer 140 and sidewalls of the first trench O1. The space SP has a width W3. In some embodiments, the width W3 is less than the first width W1, and the width of the space SP is, for instance, 1 μm to 50 μm, which should not be construed as a limitation in the disclosure. Thereby, an orthogonal projection of the ohmic contact layer 140 on the growth substrate 10 partially overlaps an orthogonal projection of the first type semiconductor layer 110 on the growth substrate 10, and a part of the surface of the first type semiconductor layer 110 may be exposed.

In some embodiments, the cross-section of the ohmic contact layer 140 may be shaped as a trapezoid. An upper surface 140T of the ohmic contact layer 140 may be a flat surface, which should not be construed as a limitation in the disclosure. In addition, the ohmic contact layer 140 disposed in the first trench O1 may be the finger portions FP and may be arranged around the light emitting layer 120 and the second type semiconductor layer 130 or may surround the light emitting layer 120 and the second type semiconductor layer 130, which should not be construed as a limitation in the disclosure. Space SP exists between the finger portions FP and the light emitting layer 120 or the second type semiconductor layer 130.

Please refer to FIG. 2G and FIG. 2H. FIG. 2H is a schematic partially enlarged view of the region R2 in FIG. 2G. A first conductor layer 151 is formed on the upper surface 140T of the ohmic contact layer 140. In some embodiments, the first conductor layer 151 is conformal to the ohmic contact layer 140, for instance. For instance, the first conductor layer 151 covers the ohmic contact layer 140, and the contour of the orthogonal projection of the first conductor layer 151 on the growth substrate 10 is similar to the contour of the orthogonal projection of the ohmic contact layer 140 on the growth substrate 10. The orthogonal projection of the first conductor layer 151 on the growth substrate 10 may be located on the outside of the orthogonal projection of the ohmic contact layer 140 on the growth substrate 10, which should not be construed as a limitation in the disclosure. In some embodiments, the orthogonal projection of the first conductor layer 151 on the growth substrate 10 may be located within the orthogonal projection of the ohmic contact layer 140 on the growth substrate 10.

It can be learned from FIG. 2G and FIG. 2H that the first conductor layer 151 may completely cover the ohmic contact layer 140 and directly contact the first type semiconductor layer 110. As such, the first conductor layer 151 may be directly electrically connected to the first type semiconductor layer 110. The orthogonal projection of the first conductor layer 151 on the growth substrate 10 partially overlaps an orthogonal projection of the first type semiconductor layer 110 on the growth substrate 10. A portion of the surface of the first type semiconductor layer 110 may be exposed. In addition, the first conductor layer 151 is isolated from the light emitting layer 120 and the second type semiconductor layer 130.

In some embodiments, the first conductor layer 151 is, for instance, a single metal layer or a stack of multiple metal layers, which should not be construed as a limitation in the disclosure. A material of the first conductor layer 151 includes chromium (Cr), titanium (Ti), aluminum (Al), aluminum alloy (Alloy Al), aluminum-copper alloy (Alloy Al/Cu), silver (Ag), nickel (Ni), palladium (Pd), platinum (Pt), gold (Au), or a combination thereof.

Note that it is difficult for metal materials to directly form an ohmic contact on the first type semiconductor layer 110. According to an embodiment of the disclosure, the ohmic contact layer 140 and the first type semiconductor layer 110 have heterogeneous structures. A lattice constant of the ohmic contact layer 140 does not match a lattice constant of the first type semiconductor layer 110. Therefore, after the epitaxial structure of the ohmic contact layer 140 is formed on the surface of the first type semiconductor layer 110, the first conductor layer 151 made of metal may be formed on the ohmic contact layer 140, so as to complete the process of arranging the ohmic contact structure on the first type semiconductor layer 110. Under the above configuration, the first conductor layer 151 and the ohmic contact layer 140 may form a structure with low resistance and ohmic contact characteristics on the first type semiconductor layer 110. As such, electrical properties of the first type semiconductor layer 110 may be improved. The light emitting device 1 may have favorable performance and quality. In addition, the manufacturing process of the light emitting device 1 may be simple and cost-saving.

With reference to FIG. 21, a second conductor layer 152 is formed on the second type semiconductor layer 130. The second conductor layer 152 and the second type semiconductor layer 130 are electrically connected to each other. In some embodiments, an orthogonal projection of the second conductor layer 152 on the growth substrate 10 is located within an orthogonal projection of the second type semiconductor layer 130 on the growth substrate 10, which should not be construed as a limitation in the disclosure. In other embodiments, the contour of the second conductor layer 152 may be similar to or aligned to the contour of the second type semiconductor layer 130.

In some embodiments, a material and a structure of the second conductor layer 152 are similar to those of the first conductor layer 151 and include a stack of metal layers or metal alloy. In other embodiments, the material of the second conductor layer 152 further includes indium tin oxide (ITO), zinc oxide (ZnO), aluminum zinc oxide (AlZnO), gallium zinc oxide (GaZnO), or other suitable transparent conductive materials. As such, a light-exit area of the light emitting component 100 may be increased. In addition, the second conductor layer 152 and the second type semiconductor layer 130 may have low resistance and ohmic contact characteristics.

In some embodiments, a thickness of the second conductor layer 152 is, for instance, 0 angstroms to 500 angstroms, which should not be construed as a limitation in the disclosure. The thickness of the second conductor layer 152 may be smaller than the thickness of the first conductor layer 151, which should not be construed as a limitation in the disclosure.

So far, the production of the light emitting component 100 is substantially completed. The production of the light emitting device 1 will be further explained below.

With reference to FIG. 2J, a first current conducting layer 161 and a second current conducting layer 162 are then formed. The first current conducting layer 161 is formed on the first conductor layer 151 and is electrically connected to the first conductor layer 151. The first conductor layer 151 is located between the ohmic contact layer 140 and the first current conducting layer 161. The first current conducting layer 161 is electrically connected to the first type semiconductor layer 110 through the first conductor layer 151 and the ohmic contact layer 140. The second current conducting layer 162 is formed on the second conductor layer 152 and is electrically connected to the second conductor layer 152. The second current conducting layer 162 is electrically connected to the second type semiconductor layer 130 through the second conductor layer 152. In some embodiments, an orthogonal projection of the first current conducting layer 161 on the growth substrate 10 overlaps the orthogonal projection of the first conductor layer 151 on the growth substrate 10. An orthogonal projection of the second current conducting layer 162 on the growth substrate 10 overlaps the orthogonal projection of the second conductor layer 152 on the growth substrate 10. In some embodiments, a thickness of the first current conducting layer 161 is greater than the thickness of the first conductor layer 151, which should not be construed as a limitation in the disclosure. A thickness of the second current conducting layer 162 is greater than the thickness of the second conductor layer 152, which should not be construed as a limitation in the disclosure.

In some embodiments, materials and structures of the first current conducting layer 161 and the second current conducting layer 162 are similar to those of the first conductor layer 151, including a stack of metal layers or metal alloy; hence, no repetitive description is provided hereinafter. In another embodiment, the first current conducting layer 161 and the second current conducting layer 162 may also be formed in the same step of forming the first conductor layer 151 and the second conductor layer 152. In some other embodiments, it is likely not to form any current conducting layer which may be directly replaced by the conductor layer.

With reference to FIG. 2K, a stack 220 of insulation layers (shown in FIG. 2M) is formed on the light emitting component 100. The stack 220 of insulation layers includes a first insulation layer 211 and a second insulation layer 212. The detailed description is provided below.

After the steps of forming the first current conducting layer 161 and the second current conducting layer 162, the first insulation layer 211 is formed on the light emitting component 100. Specifically, the first insulation layer 211 covers the undoped semiconductor layer 12, the first type semiconductor layer 110, the light emitting layer 120, the second type semiconductor layer 130, the ohmic contact layer 140, the first conductor layer 151, the second conductor layer 152, the first current conducting layer 161, and the second current conducting layer 162. A material of the first insulation layer 221 includes a single layer of an insulation material or multiple layers of insulation materials which have different refractive indices and are alternately stacked, wherein the stacked structure of insulation materials with different refractive indexes includes, for instance, a stacked structure of silicon dioxide and titanium dioxide (SiO₂/TiO₂) or a stacked structure of silicon dioxide and tantalum pentoxide (SiO₂/Ta₂O₅).

In some embodiments, the first insulation layer 221 may be a reflection layer. For instance, the first insulation layer 221 may include a distributed Bragg reflector (DBR) formed by stacking a plurality of insulation layers with different refractive indexes.

In an embodiment not shown in the drawings, the first insulation layer 221 may include an upper insulation layer, a lower insulation layer, and a DBR located between the upper insulation layer and the lower insulation layer. In the above embodiment, materials and thicknesses of the upper and lower insulation layers may affect a reflective wavelength range of the DBR. Owing to the upper and lower insulation layers with varying thicknesses, the DBR is allowed to have an expanded reflective wavelength range and is thus suitable for end products that require a light output effect in a wide wavelength range. However, the way to apply the above materials and the light emitting device is only provided for illustrative purposes. In fact, when the DBR is made of other materials, the application manner may be adjusted according to the present reflective wavelength range. Under the above configuration, when the first insulation layer 221 is a reflection layer, a light beam emitted by the light emitting layer 120 of the light emitting unit 100 may be collectively reflected toward of the growth substrate 10, so as to improve a light output effect and a light output rate of the light emitting device 1.

It can be seen from FIG. 2K that the first insulation layer 221 may be patterned to form a plurality of openings O3 and O4 in the first insulation layer 221. The openings O3 and O4 expose the first current conducting layer 161 and the second current conducting layer 162, respectively.

With reference to FIG. 2L, a first connection layer 171, a second connection layer 172, and a third connection layer 173 are formed on the first insulation layer 211. Materials of the first connection layer 171, the second connection layer 172, and the third connection layer 173 are similar to that of the first conductor layer 151; hence, no repetitive description is provided hereinafter. The first connection layer 171 is electrically connected to the first current conducting layer 161 through the openings O3. The first connection layer 171 is electrically connected to the first type semiconductor layer 110 through the first current conducting layer 161, the first conductor layer 151, and the ohmic contact layer 140. The second connection layer 172 is electrically connected to the second current conducting layer 162 through the openings O4. The second connection layer 172 is electrically connected to the second type semiconductor layer 130 through the second current conducting layer 162 and the second conductor layer 152. In some embodiments, the third current conducting layer 173 is not electrically connected to the light emitting component 100 but is in an electrically floating state and is disposed on the first insulation layer 221. Under the above configuration, the third current conducting layer 173 may serve as a test pad for performing an electrical test on the light emitting device 1 during the manufacturing process.

With reference to FIG. 2M, a second insulation layer 222 is formed on the first insulation layer 221. The second insulation layer 222 covers the first connection layer 171, the second connection layer 172, and the third connection layer 173. Thereby, the stack 220 of insulation layers including the first insulation layer 221 and the second insulation layer 222 may serve to isolate the first connection layer 171, the second connection layer 172, and the third connection layer 173. The second insulation layer 222 is disposed on the first insulation layer 221 (i.e., the reflection layer). A material of the second insulation layer 222 includes SiO₂, TiO₂, or other suitable materials, which should not be construed as a limitation in the disclosure.

It can be seen from FIG. 2M that the second insulation layer 222 may be patterned, so that the second insulation layer 222 may have a plurality of openings O5 and O6. The openings O5 correspondingly overlap the first connection layer 171 and expose the first connection layer 171. The openings O6 correspondingly overlap the second connection layer 172 and exposes the second connection layer 172.

With reference to FIG. 2N, a first conductive bump 181 and a second conductive bump 182 are formed. The first conductive bump 181 and the second conductive bump 182 are correspondingly electrically connected to the first connection layer 171 and the second connection layer 172 through the openings O5 and the openings O6 of the second insulation layer 222, respectively. Specifically, the first conductive bump 181 correspondingly overlaps the openings O5. The second conductive bump 182 correspondingly overlaps the openings O6. Under the above configuration, the first conductive bump 181 may be electrically connected to the first conductor layer 151 through the first connection layer 171 and the first current conducting layer 161 and may be electrically connected to the ohmic contact layer 140 and the first type semiconductor layer 110. The second conductive bump 182 may be electrically connected to the second conductor layer 152 through the second connection layer 172 and the second current conducting layer 162 and may be electrically connected to the second type semiconductor layer 130. Thereby, the first conductive bump 181 may serve as a negative electrode of the light emitting device 1 (e.g., taking the first type semiconductor layer as an N-type semiconductor layer), and the second conductive bump 182 may serve as a positive electrode of the light emitting device 1 (e.g., taking the second type semiconductor layer as a P-type semiconductor layer).

In some embodiments, the first conductive bump 181 and the second conductive bump 182 may be conductive pads, conductive pillars, or conductive balls. The first conductive bump 181 and the second conductive bump 182 include solder materials or metal. For instance, the material of the first conductive bump 181 and the second conductive bump 182 includes Au, tin (Sn), gold-tin alloy, tin alloy, tin-silver-copper alloy, or a combination thereof, which should not be construed as a limitation in the disclosure.

In short, in the light emitting device 1 provided in an embodiment of the disclosure, since the light emitting unit 100 includes the ohmic contact layer 140 electrically connected to the first type semiconductor layer 110, and the first conductor layer 151 conformally covers the ohmic contact layer 140, the first conductor layer 151 made of metal and the ohmic contact layer 140 having the epitaxial structure may form a structure with low resistance and ohmic contact characteristics on the first type semiconductor layer 110. As such, electrical properties of the first type semiconductor layer 110 may be improved. In addition, the first insulation layer 221 is capable of collectively reflecting the light beam emitted by the light emitting layer 120 of the light emitting unit 100, so as to improve the light output effect and the light output rate of the light emitting device 1. Thereby, the light emitting device 1 may have favorable performance and quality. Besides, the manufacturing process of the light emitting device 1 may be simple and cost-saving.

Note that the reference numbers and parts of the descriptions provided in the previous embodiments are also applied in the following embodiments, the same reference numbers serve to represent the same or similar components, and the description of the same technical content is omitted. The description of the omitted parts may be referred to as those provided in the previous embodiments and will not be repeated in the following embodiments.

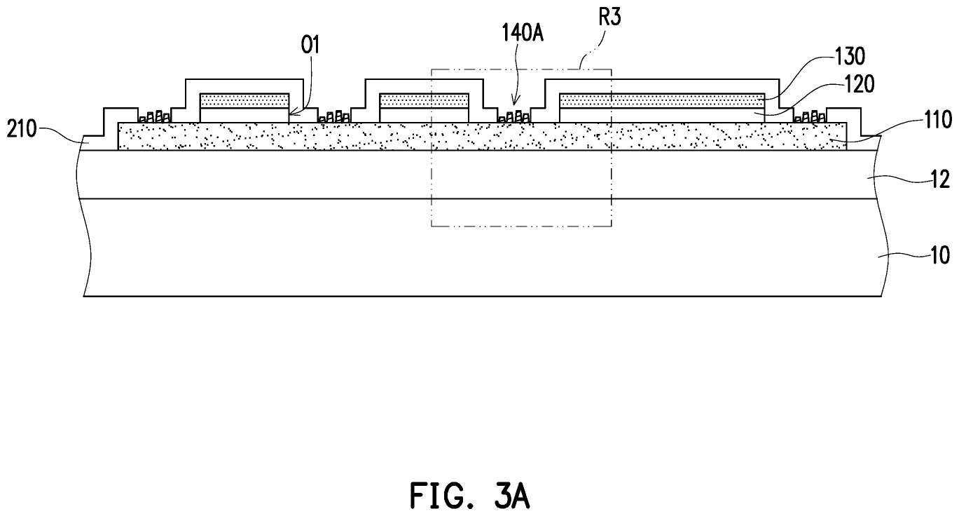

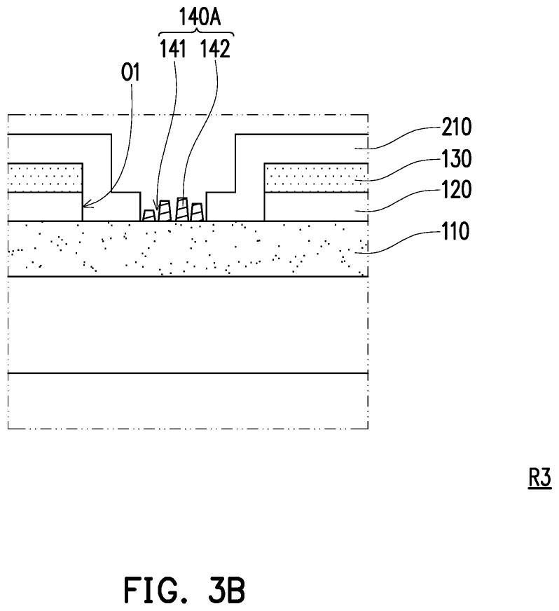

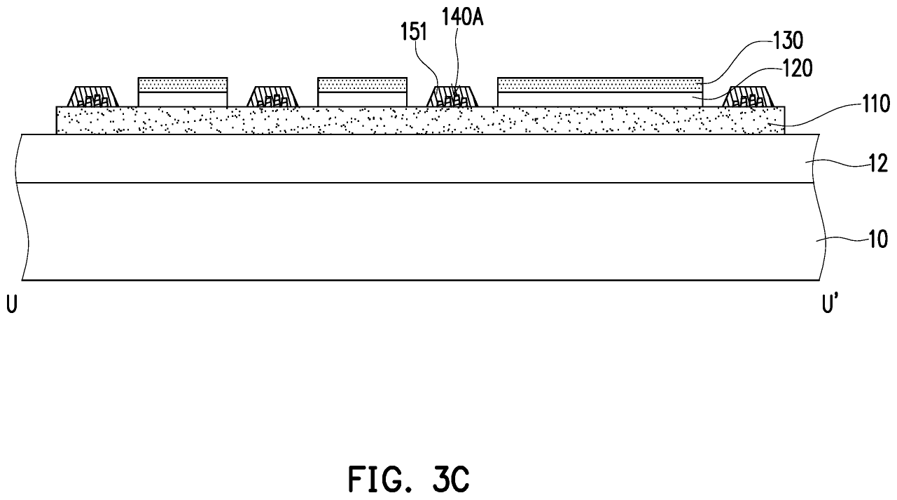

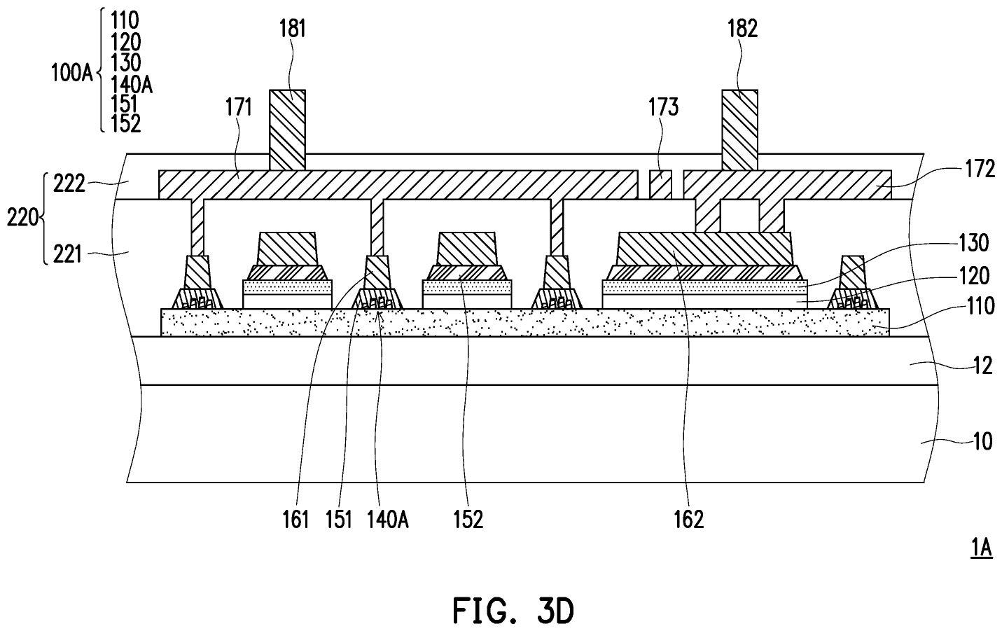

FIG. 3A to FIG. 3D are schematical cross-sectional views illustrating a manufacturing method of a light emitting device according to another embodiment of the disclosure. FIG. 3B is a schematic partially enlarged view of an ohmic contact layer according to another embodiment of the disclosure. For the clarity of the drawings and easy explanation, some components are omitted from FIG. 3A to FIG. 3D. A light emitting device 1A provided in the embodiment is similar to the light emitting device 1 depicted in FIG. 2A to FIG. 2N, while the difference lies in that an ohmic contact layer 140A provided in the embodiment includes a plurality of vias 141 and island portions 142 surrounding the vias 141.

It can be seen from FIG. 3A and FIG. 3B that the island portions 142 of the ohmic contact layer 140A may be electrically connected to the first type semiconductor layer 110, and the vias 141 may extend in a direction perpendicular to the growth substrate 10. The vias 141 may expose a portion of the first type semiconductor layer 110. In some embodiments, compared with the ohmic contact layer 140 depicted in FIG. 2F, the ohmic contact layer 140A provided in the embodiment may be heated in a shortened period of time, or the heating temperature may be raised or lowered, which results in the relatively rough epitaxial structure of the ohmic contact layer 140A. Thereby, a contact area of the ohmic contact layer 140A may be increased.

With reference to FIG. 3C and FIG. 3D, the first conductor layer 151 is formed on the ohmic contact layer 140A. The first conductor layer 151 fills the vias 141 to contact the first type semiconductor layer 110. The first current conducting layer 161, the second current conducting layer 162, the first connection layer 171, the second connection layer 172, the third connection layer 173, the first conductive bump 181, the second conductive bump 182, and the stack 220 of insulation layers are then sequentially formed, so as to complete the configuration of the light emitting device 1A. Under the above configuration, a contact area between the first conductor layer 151 and the ohmic contact layer 140A may be increased, so as to further reduce the resistance. In addition, a bonding force between the first conductor layer 151 and the ohmic contact layer 140A may be improved. Besides, since the ohmic contact layer 140A has the vias 141, the aperture rate may be increased to enhance the light output effect. As such, the performance and the structural quality of the light emitting component 100A and the light emitting device 1A may be improved.

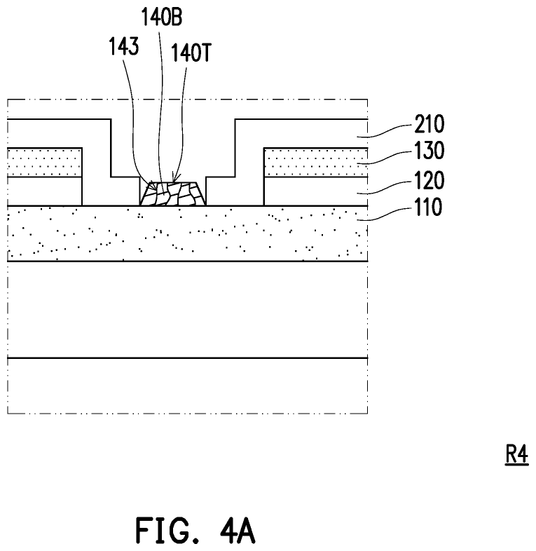

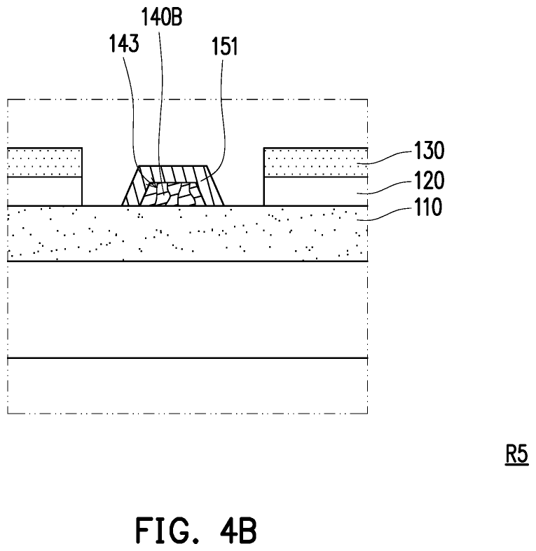

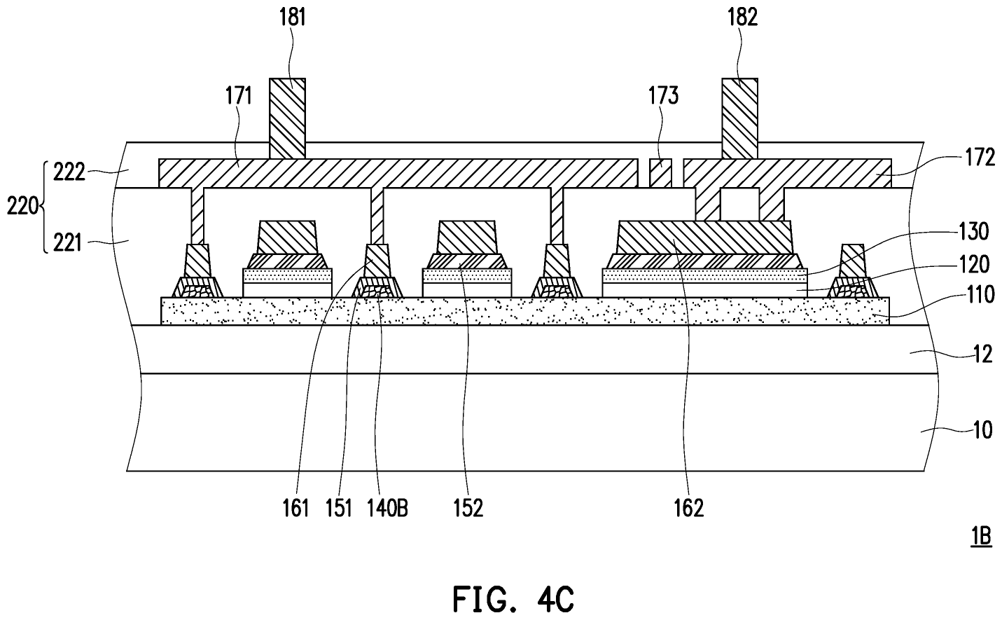

FIG. 4A to FIG. 4C are schematic cross-sectional views illustrating a manufacturing method of a light emitting device according to another embodiment of the disclosure. FIG. 4A is a schematic partially enlarged view of an ohmic contact layer according to another embodiment of the disclosure. FIG. 4B is a schematic partially enlarged view of an ohmic contact layer according to another embodiment of the disclosure. For the clarity of the drawings and easy explanation, some components are omitted from FIG. 4A to FIG. 4C. A light emitting device 1B provided in the embodiment is similar to the light emitting device 1 depicted in FIG. 2A to FIG. 2N, while the difference lies in that, an ohmic contact layer 140B provided in the embodiment has a rough surface, for instance. Specifically, an upper surface 140T of the ohmic contact layer 140B is a rough surface, and the rough surface includes a plurality of micro-structures 143. The micro-structures 143 are, for instance, defects, cavities, or uneven structures on the surface. The micro-structures 143 may extend from the upper surface 140T to the first type semiconductor layer 110. The micro-structures 143 may or may not penetrate the ohmic contact layer 140B. Under the above configuration, the micro-structures 143 may increase the contact area of the ohmic contact layer 140B.

With reference to FIG. 4B and FIG. 4C, the first conductor layer 151 is formed to conformally cover the ohmic contact layer 140B. The first current conducting layer 161, the second current conducting layer 162, the first connection layer 171, the second connection layer 172, the third connection layer 173, the first conductive bump 181, the second conductive bump 182, and the stack 220 of insulation layers are then sequentially formed to complete the configuration of the light emitting device 1B. Under the above configuration, a contact area between the first conductor layer 151 and the ohmic contact layer 140B may be increased, so as to further reduce the resistance. In addition, a bonding force between the first conductor layer 151 and the ohmic contact layer 140A may be improved. Therefore, the performance and the structural quality of the light emitting device 1B may be improved.

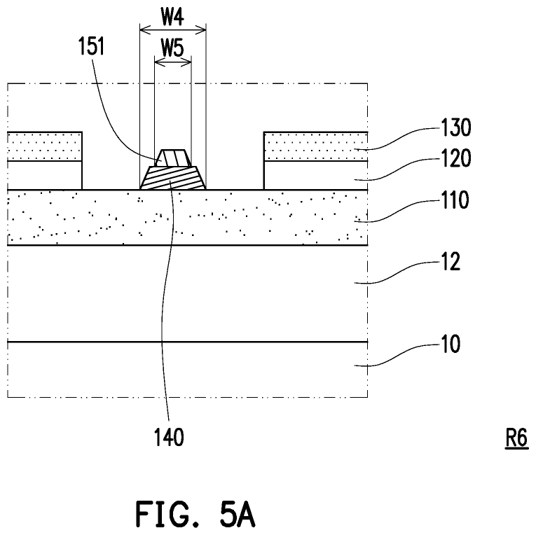

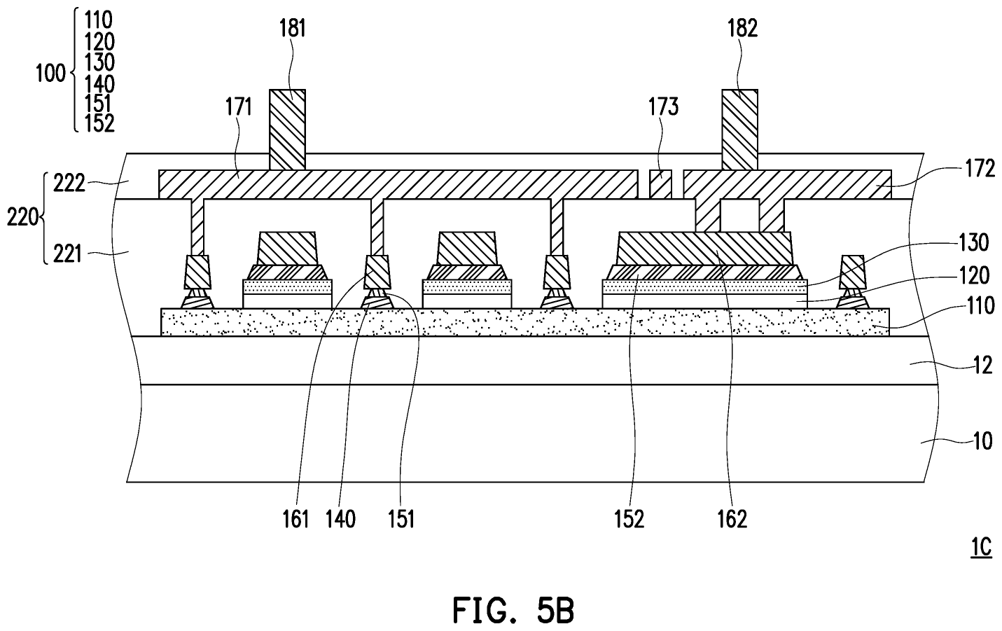

FIG. 5A to FIG. 5B are schematic cross-sectional views illustrating a manufacturing method of a light emitting device according to another embodiment of the disclosure. FIG. 5A is a schematic partially enlarged view of an ohmic contact layer according to another embodiment of the disclosure. For the clarity of the drawings and easy explanation, some components are omitted from FIG. 5A to FIG. 5B. A light emitting device 1C provided in the embodiment is similar to the light emitting device 1 depicted in FIG. 2A to FIG. 2N, while the difference lies in that the first conductor layer 151 is disposed on the ohmic contact layer 140, and the orthogonal projection of the first conductor layer 151 on the growth substrate 10 is located within the orthogonal projection of the ohmic contact layer 140 on the growth substrate 10. In some embodiments, the ohmic contact layer 140 has a width W4, and the first conductor layer 151 has a width W5. The width W4 is greater than the width W5. In some embodiments, the width W4 is, for instance, 3 μm to 100 μm. The width W5 is, for instance, 1 μm to 100 μm, which should not be construed as a limitation in the disclosure. Under the above configuration, the first conductor layer 151 does not directly contact the first type semiconductor layer 110.

The first current conducting layer 161, the second current conducting layer 162, the first connection layer 171, the second connection layer 172, the third connection layer 173, the first conductive bump 181, the second conductive bump 182, and the stack 220 of insulation layers are then sequentially formed to complete the configuration of the light emitting device 1C. Under the above configuration, the light emitting device 1C has favorable performance and structural quality.

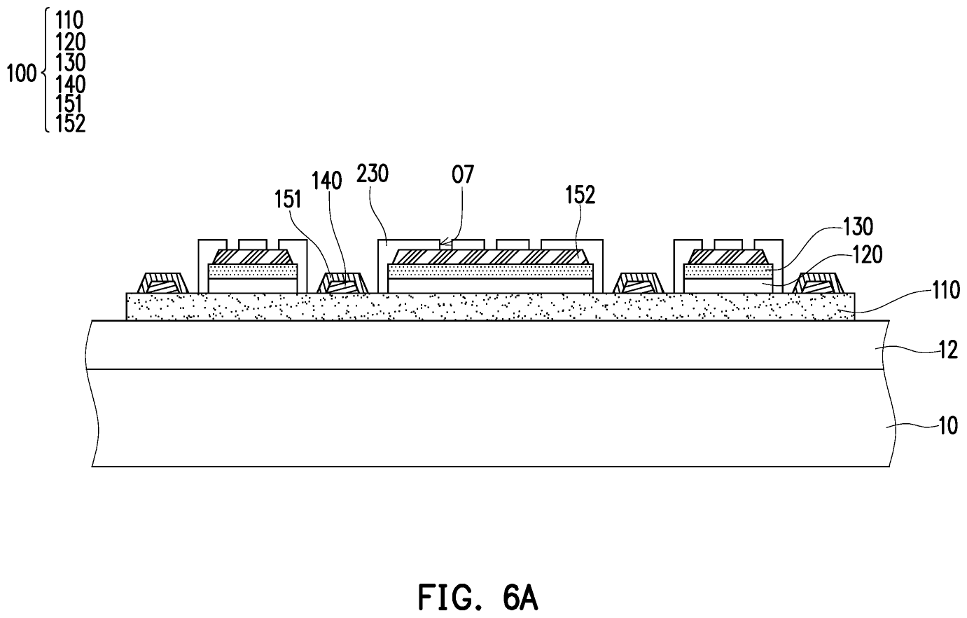

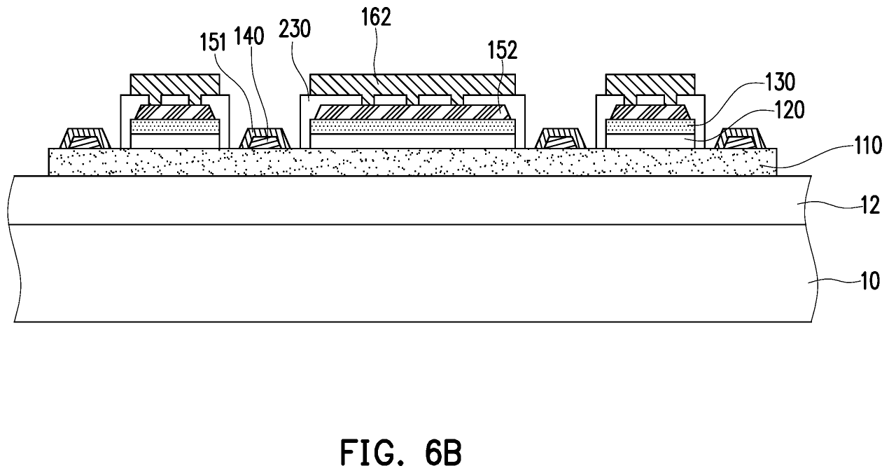

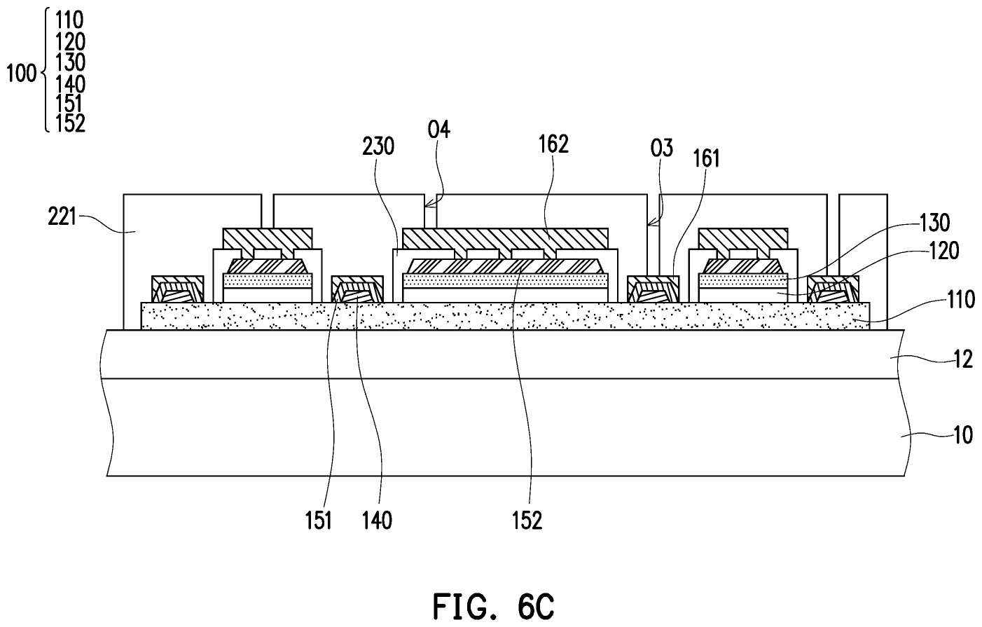

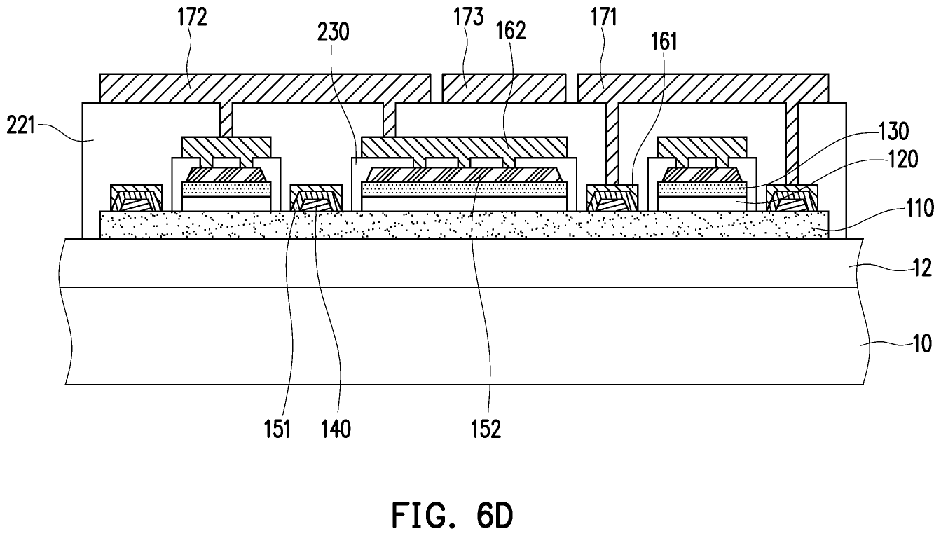

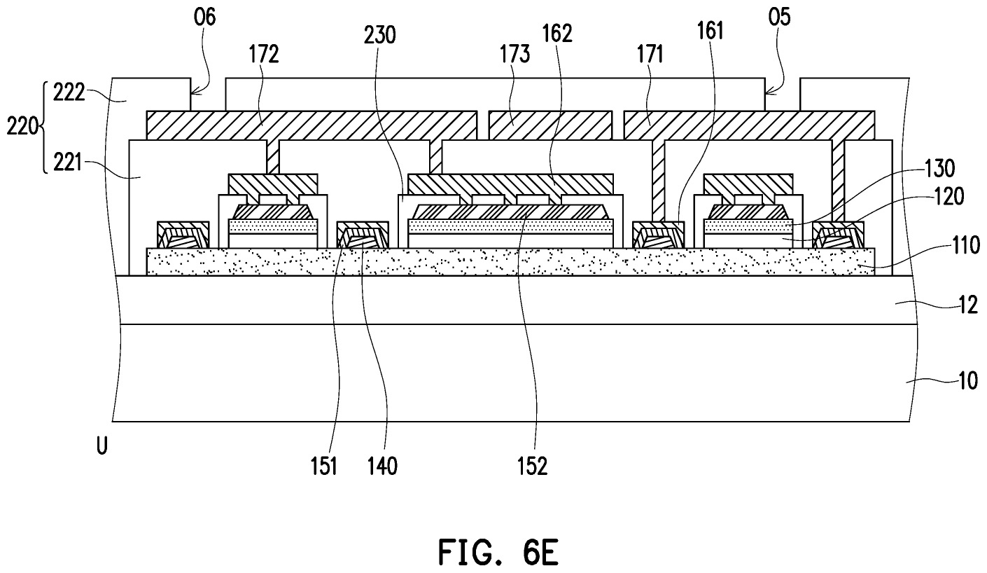

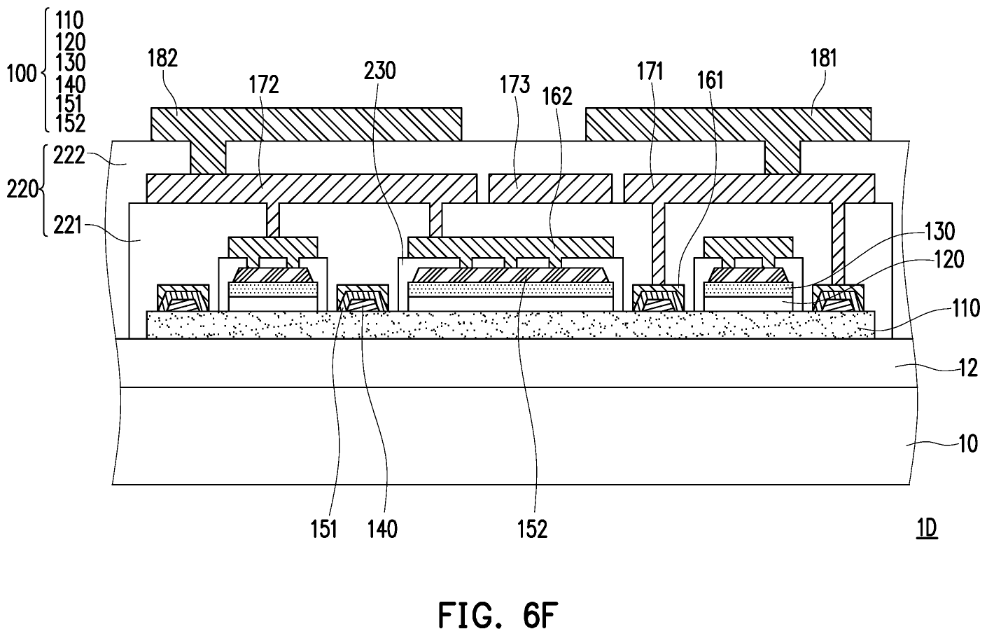

FIG. 6A to FIG. 6F are schematic cross-sectional views illustrating a manufacturing method of a light emitting device according to another embodiment of the disclosure. For the clarity of the drawings and easy explanation, some components are omitted from FIG. 6A to FIG. 6F. A light emitting device 1D provided in the embodiment is similar to the light emitting device 1 depicted in FIG. 2A to FIG. 2N, while the difference lies in that the light emitting device 1D further includes an insulative reflection layer 230, for instance. In detail, the step of forming the light emitting component 100 further includes forming the insulative reflection layer 230 on the light emitting layer 120, the second type semiconductor layer 130, and the second conductor layer 152 after the step of forming the second conductor layer 152.

Next, a plurality of openings O7 are formed in the insulative reflection layer 230. The openings O7 correspondingly overlap the second conductor layer 152 to expose the second conductor layer 152. In some embodiments, a material of the insulative reflection layer 230 includes a single layer of an insulating material or multiple layers of insulating materials, or the insulative reflection layer 230 has a structure in which a plurality of insulating material layers with different refractive indexes are alternately stacked; the latter is, for instance, a DBR, a structure of alternately stacked insulating material layers with different refractive indices, such as a stacked structure of SiO₂/TiO₂, a stacked structure of SiO₂/Ta₂O₅, or a stacked structure of SiO2 and magnesium fluoride (MgF2).

In an embodiment not shown in the drawings, the insulative reflection layer 230 may include an upper insulation layer, a lower insulation layer, and the DBR located between the upper and lower insulation layers.

In another embodiment not shown in the drawings, the insulative reflection layer 230 may include an upper insulation layer, a lower insulation layer, and a metal reflector mirror located between the upper and lower insulation layers. A material of the metal reflector mirror is, for instance, Al, Ag, or Alloy Al/Cu, which should not be construed as a limitation in the disclosure.

Under the above configuration, the insulative reflection layer 230 may collectively reflect the light beam emitted by the light emitting layer 120 of the light emitting unit 100 toward the growth substrate 10, so as to improve the light output effect and the light output rate of the light emitting device 1D.

With reference to FIG. 6B and FIG. 6C, a first current conducting layer 161 is formed on the first conductor layer 151, and a second current conducting layer 161 is formed on the insulative reflection layer 230. The insulative reflection layer 230 is electrically connected to the second conductor layer 152 through the openings O7 to be electrically connected to the second type semiconductor layer 130.

The first insulation layer 221 is then formed on the light emitting component 100 and covers the insulative reflection layer 230. The first insulation layer 221 may be a reflection layer. The first insulation layer 221 may be a single layer of a reflective insulation material or may have a structure in which a plurality of insulation materials with different refractive indexes are alternately stacked. The first insulation layer 221 may be a DBR. In some embodiments, the first insulation layer 221 may include an upper insulation layer, a lower insulation layer, and a DBR located between the upper and lower insulation layers, which should not be construed as a limitation in the disclosure. Under the above configuration, the light beam emitted by the light emitting layer 120 may be collectively reflected toward the growth substrate 10 to improve the light output effect and the light output rate of the light emitting device 1D.

In some embodiments, the first insulation layer 221 further includes the openings O3 and O4. The openings O3 and O4 expose the first current conducting layer 161 and the second current conducting layer 162, respectively.

With reference to FIG. 6D, the first connection layer 171, the second connection layer 172, and the third connection layer 173 are then formed on the first insulation layer 211. The first connection layer 171 is electrically connected to the first current conducting layer 161 through the openings O3. The second connection layer 172 is electrically connected to the second current conducting layer 162 through the openings O4. In some embodiments, the third current conducting layer 173 is not electrically connected to the light emitting component 100 but is in an electrically floating state and is disposed on the first insulation layer 221. The third current conducting layer 173 may serve as a test pad for performing an electrical test on the light emitting device 1D during the manufacturing process.

With reference to FIG. 6E, the second insulation layer 222 is formed on the first insulation layer 221. The second insulation layer 222 covers the first connection layer 171, the second connection layer 172, and the third connection layer 173. Thereby, the first connection layer 171, the second connection layer 172, and the third connection layer 173 may be isolated from one another through the first insulation layer 221 and the second insulation layer 222.

In some embodiments, the second insulation layer 222 has a plurality of openings O5 and O6. The openings O5 correspondingly overlap the first connection layer 171 and expose the first connection layer 171. The openings O6 correspondingly overlap the second connection layer 172 and expose the second connection layer 172.

With reference to FIG. 6F, the first conductive bump 181 and the second conductive bump 182 are formed. The first conductive bump 181 and the second conductive bump 182 are correspondingly electrically connected to the first connection layer 171 and the second connection layer 172 through the openings O5 and O6 of the second insulation layer 222, respectively. The first conductive bump 181 and the second conductive bump 182 may be conductive pads, conductive pillars, or conductive balls.

Under the above configuration, the light emitting device 1D may further concentrate the light beam emitted by the light emitting layer 120 through the insulative reflection layer 230, so as to improve the light output effect and quality. In addition, the light emitting device 1D further has favorable performance and structural quality.

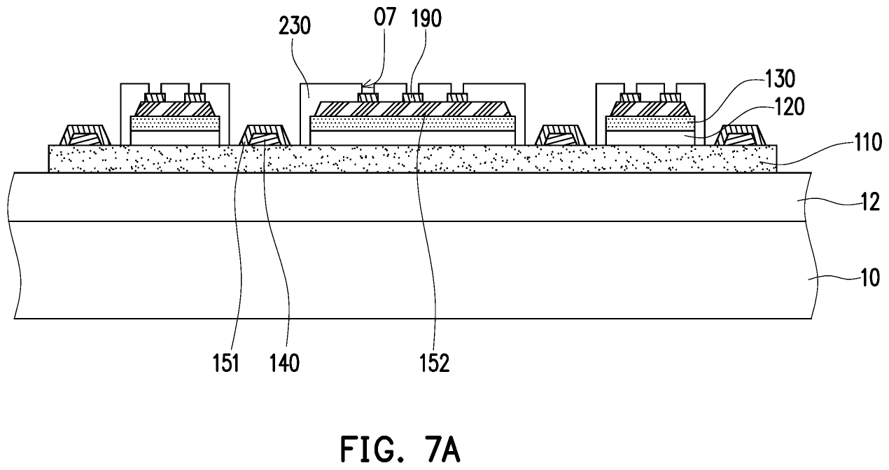

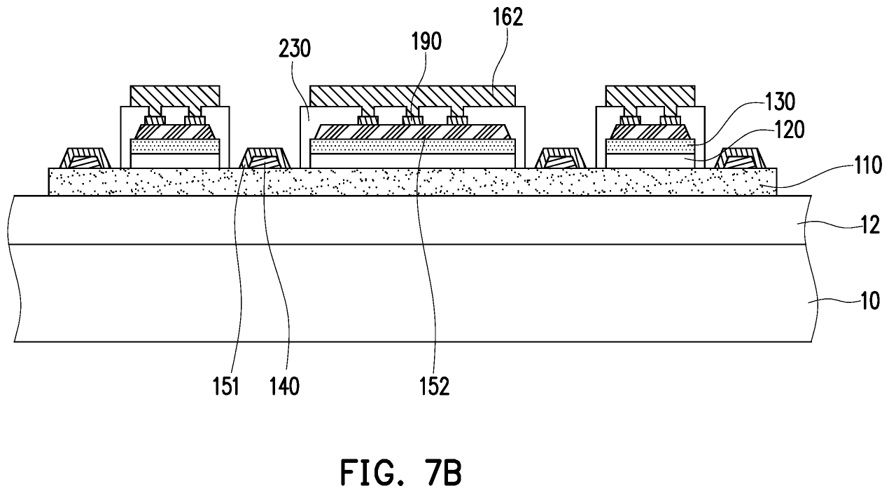

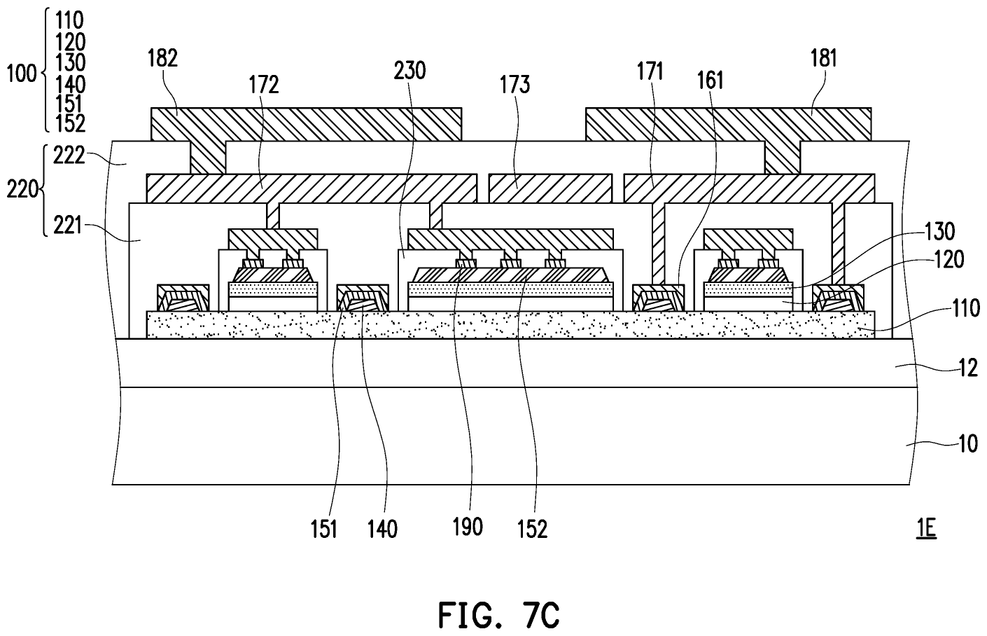

FIG. 7A to FIG. 7C are schematic cross-sectional views illustrating a manufacturing method of a light emitting device according to another embodiment of the disclosure. For the clarity of the drawings and easy explanation, some components are omitted from FIG. 7A to FIG. 7C. A light emitting device 1E provided in the embodiment is similar to the light emitting device 1D depicted in FIG. 6A to FIG. 6F, while the difference lies in that the light emitting device 1E further includes a plurality of conductive members 190 disposed on the second conductor layer 152, for instance. A material of the conductive members 190 is similar to that of the first conductor layer 151; hence, no repetitive description is provided hereinafter.

An orthogonal projection of any conductive member 190 on the growth substrate 10 overlaps the orthogonal projection of the second conductor layer 152 on the growth substrate 10. In some embodiments, the orthogonal projection of the conductive members 190 on the growth substrate 10 is located in the orthogonal projection of the second conductor layer 152 on the growth substrate 10. In other embodiments, an area of the orthogonal projection of the conductive members 190 on the growth substrate 10 is smaller than an area of the orthogonal projection of the first conductor layer 151 on the growth substrate 10.

In some embodiments, the insulative reflection layer 230 is disposed on the second type semiconductor layer 130 and the second conductor layer 152. The insulative reflection layer 230 has a plurality of openings O7. The openings O7 correspondingly overlap the conductive members 190 to expose the conductive members 190.

With reference to FIG. 7B and FIG. 7C, the first current conducting layer 161 is formed on the first conductor layer 151, and the second current conducting layer 161 is formed on the insulative reflection layer 230. The insulative reflection layer 230 is electrically connected to the conductive members 190 through the openings O7, so as to be electrically connected to the second type semiconductor layer 130.

The first connection layer 171, the second connection layer 172, the third connection layer 173, the first conductive bump 181, the second conductive bump 182, and the stack 200 of insulation layers are then sequentially formed to complete the configuration of the light emitting device 1E. Under the above configuration, the light emitting device 1E may further reduce the resistance of the second conductor layer 152 and the second current conducting layer 162 through the conductive members 190. The light emitting device 1E has good performance and structural quality.

To sum up, in the light emitting device provided in one or more embodiments of the disclosure, the ohmic contact layer is electrically connected to the first type semiconductor layer, and the first conductor layer contacts the ohmic contact layer, so that the first conductor layer made of metal and the ohmic contact layer having the epitaxial structure may form a structure with low resistance and ohmic contact characteristics on the first type semiconductor layer. Thereby, the electrical properties of the first type semiconductor layer may be improved. In addition, the first insulation layer or the insulative reflection layer may collectively reflect the light beam emitted by the light emitting layer of the light emitting unit, so as to improve the light output effect and the light output rate of the light emitting device. As such, the light emitting device may have favorable performance and quality. In addition, the manufacturing process of the light emitting device may be simple and cost-saving.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A light emitting device, comprising:
a growth substrate;
a light emitting component, disposed on the growth substrate and comprising:
a first type semiconductor layer;
a second type semiconductor layer;
a light emitting layer, located between the first type semiconductor layer and the second type semiconductor layer, wherein the light emitting layer and the second type semiconductor layer have a trench penetrating the light emitting layer and the second type semiconductor layer;
an ohmic contact layer, disposed on the first type semiconductor layer, located in the trench, and electrically connected to the first type semiconductor layer;
a first conductor layer, disposed on the first type semiconductor layer and located in the trench, the first conductor layer covering the ohmic contact layer and being electrically connected to the ohmic contact layer; and
a second conductor layer, disposed on and electrically connected to the second type semiconductor layer;
a first conductive bump, electrically connected to the first type semiconductor layer through the first conductor layer and the ohmic contact layer; and
a second conductive bump, electrically connected to the second type semiconductor layer through the second conductor layer.

2. The light emitting device according to claim 1, wherein the first conductor layer and the first type semiconductor layer are directly electrically connected.

3. The light emitting device according to claim 1, wherein the light emitting component further comprises:
a first current conducting layer, disposed on the first conductor layer, the first current conducting layer being electrically connected to the first type semiconductor layer through the first conductor layer and the ohmic contact layer; and
a second current conducting layer, disposed on the second conductor layer, the second current conducting layer being electrically connected to the second type semiconductor layer through the second conductor layer.

4. The light emitting device according to claim 3, wherein the first conductor layer is located between the ohmic contact layer and the first current conducting layer.

5. The light emitting device according to claim 1, wherein a material of the ohmic contact layer comprises a III-V group compound.

6. The light emitting device according to claim 1, wherein a lattice constant of the ohmic contact layer does not match a lattice constant of the first type semiconductor layer.

7. The light emitting device according to claim 1, further comprising:
a stack of insulation layers, disposed on the light emitting component and comprising:
a first insulation layer; and
a second insulation layer, disposed on the first insulation layer;
a first connection layer, disposed on the first insulation layer, the first connection layer being electrically connected to the first type semiconductor layer through the first conductor layer; and
a second connection layer, disposed on the first insulation layer, the second connection layer being electrically connected to the second type semiconductor layer through the second conductor layer,
wherein the second insulation layer covers the first connection layer and the second connection layer, and the first connection layer is electrically insulated from the second connection layer by the first insulation layer and the second insulation layer.

8. The light emitting device according to claim 7, wherein the first conductive bump is electrically connected to the first conductor layer through the first connection layer, and the second conductive bump is electrically connected to the second conductor layer through the second connection layer.

9. The light emitting device according to claim 7, further comprising a third connection layer in an electrically floating state, wherein the third connection layer is disposed on the first insulation layer and is electrically insulated from the first connection layer or the second connection layer by the first insulation layer and the second insulation layer.

10. The light emitting device according to claim 1, further comprising an undoped semiconductor layer located between the growth substrate and the light emitting component.

11. The light emitting device according to claim 1, wherein the ohmic contact layer comprises a plurality of vias and island portions surrounding the vias, and the first conductor layer fills the vias to contact the first type semiconductor layer.

12. The light emitting device according to claim 1, wherein the ohmic contact layer comprises a rough surface, and the rough surface comprises a plurality of micro-structures.

13. A light emitting device, comprising:
a growth substrate;
a light emitting component, disposed on the growth substrate and comprising:
a first type semiconductor layer;
a second type semiconductor layer;
a light emitting layer, located between the first type semiconductor layer and the second type semiconductor layer, wherein the light emitting layer and the second type semiconductor layer have a trench penetrating the light emitting layer and the second type semiconductor layer;
an ohmic contact layer, disposed on the first type semiconductor layer, located in the trench, and electrically connected to the first type semiconductor layer, the ohmic contact layer having a plurality of finger portions;
a first conductor layer, disposed on an upper surface of the ohmic contact layer and located in the trench, the first conductor layer being electrically connected to the ohmic contact layer; and
a second conductor layer, disposed on and electrically connected to the second type semiconductor layer.

14. The light emitting device according to claim 13, wherein the finger portions are located in the trench, and space exists between the finger portions and the second type semiconductor layer.

15. The light emitting device according to claim 13, wherein the light emitting component further comprises an insulative reflection layer disposed on the light emitting layer, the second type semiconductor layer, and the second conductor layer, and the insulative reflection layer comprises a plurality of openings.

16. The light emitting device according to claim 15, further comprising:
a first current conducting layer, disposed on the first conductor layer and electrically connected to the first type semiconductor layer through the first conductor layer and the ohmic contact layer; and
a second current conducting layer, disposed on the insulative reflection layer, the insulative reflection layer being electrically connected to the second conductor layer through the openings, so that the insulative reflection layer is electrically connected to the second type semiconductor layer.

17. The light emitting device according to claim 16, further comprising:
a stack of insulation layers, disposed on the light emitting component and comprising:
a reflection layer; and
an insulation layer, disposed on the reflection layer;
a first connection layer, disposed on the reflection layer, the first connection layer being electrically connected to the first type semiconductor layer through the first current conducting layer; and
a second connection layer, disposed on the reflection layer, the second connection layer being electrically connected to the second type semiconductor layer through the second current conducting layer,
wherein the insulation layer covers the first connection layer and the second connection layer.

18. A manufacturing method of a light emitting device, comprising:
providing a growth substrate;
forming an undoped semiconductor layer on the growth substrate;
forming a light emitting component on the undoped semiconductor layer, comprising:
forming a first type semiconductor layer on the undoped semiconductor layer;
forming a light emitting layer on the first type semiconductor layer;
forming a second type semiconductor layer on the light emitting layer;
performing a first etching process to pattern the light emitting layer and the second type semiconductor layer, wherein at least one first trench is formed in the light emitting layer and the second type semiconductor layer and exposes the first type semiconductor layer;
forming a sacrificial layer covering the first type semiconductor layer, the light emitting layer, and the second type semiconductor layer;
performing a second etching process to pattern the sacrificial layer, wherein at least one second trench is formed in the sacrificial layer, and an orthogonal projection of the at least one second trench on the growth substrate is located in an orthogonal projection of the at least one first trench on the growth substrate;
forming an ohmic contact layer in the at least one second trench;
removing the sacrificial layer;
forming a first conductor layer on the ohmic contact layer, the first conductor layer being electrically connected to the ohmic contact layer; and
forming a second conductor layer on the second type semiconductor layer;
forming a first current conducting layer electrically connected to the first conductor layer, and forming a second current conducting layer electrically connected to the second conductor layer;
forming a first insulation layer on the light emitting component, the first insulation layer having a plurality of openings respectively exposing the first current conducting layer and the second current conducting layer;
forming a first connection layer, a second connection layer, and a third connection layer on the first insulation layer, the first connection layer and the second connection layer being correspondingly electrically connected to the first current conducting layer and the second current conducting layer through the openings of the first insulation layer, respectively, wherein the third connection layer is in an electrically floating state;
forming a second insulation layer on the first insulation layer, the second insulation layer isolating the first connection layer, the second connection layer, and the third connection layer, wherein the second insulation layer comprises a plurality of openings; and
forming a first conductive bump and a second conductive bump, the first conductive bump and the second conductive bump being correspondingly electrically connected to the first connection layer and the second connection layer through the openings of the second insulation layer, respectively.

19. The manufacturing method according to claim 18, wherein the step of forming the light emitting component further comprises:
forming an insulative reflection layer on the light emitting layer, the second type semiconductor layer, and the second conductor layer,
wherein the second current conducting layer is electrically connected to the second conductor layer through a plurality of openings of the insulative reflection layer.

20. The manufacturing method according to claim 18, wherein the at least one first trench has a first width, the at least one second trench has a second width, and the first width is greater than the second width.
